(19) United States
(12) Patent Application Publication
(10) Pub. No.: US 2025/0169306 A1
(43) Pub. Date: May 22, 2025

(54) DISPLAY DEVICE

(71) Applicant: LG DISPLAY CO., LTD., Seoul (KR)

(72) Inventors: Jeon Phill HAN, Paju-si (KR); Yong In PARK, Paju-si (KR); Seung Han PAEK, Paju-si (KR); Kyung Jae YOON, Paju-si (KR); Yu Cheol YANG, Paju-si (KR)

(73) Assignee: LG DISPLAY CO., LTD., Seoul (KR)

(21) Appl. No.: 18/953,743

(22) Filed: Nov. 20, 2024

(30) Foreign Application Priority Data
Nov. 20, 2023 (KR) 10-2023-0160378

(51) Int. Cl. H10K 59/131

(52) U.S. Cl. CPC H10K 59/131

(57) ABSTRACT

A display device can include a substrate disposed in a display area and a non-display area of a display panel, an etch-stop layer disposed on the substrate, a pad part and a bridge disposed on the substrate, the pad part and the bridge being spaced apart from each other, a first wiring line having a first side connected to the bridge and a second side opposite to the first side, the second side being an end portion of the first wiring line, and a second wiring line disposed between the pad part and the bridge.

### CROSS-REFERENCE TO RELATED APPLICATION

This application claims priority to and the benefit of Korean Patent Application No. 10-2023-0160378, filed in the Republic of Korea, on Nov. 20, 2023, the entirety of which is incorporated herein by reference into the present application.

### BACKGROUND

### 1. Field

Embodiments relates to a display device.

### 2. Discussion of Related Art

With the arrival of the information age, the field of display devices that visually display electrical information signals is advancing, and research is continuing to develop various display devices with better performance in thinness, lightness, and low power consumption.

Display devices include a liquid crystal display (LCD) apparatus, a quantum dot display (QD) apparatus, an organic light-emitting display (OLED) apparatus, an inorganic light-emitting display (LED) apparatus, and an electrophoretic display (ED) apparatus.

Display devices such as an LCD apparatus, a QD apparatus, an OLED apparatus, an LED apparatus, and an ED apparatus often undergo a test process to test a display panel. In the test process, an auto-probe test can be used that is capable of performing an overall electrical inspection of the display panel (such as short-circuiting in wiring and lighting inspection). The auto-probe test is performed by contacting a test needle with an auto-probe test pad (hereinafter referred to as “AP pad”) formed on the display panel and then applying an electrical test signal. The test signal is applied to the display panel through test lines connected to the AP pad (hereinafter referred to as “AP lines”). Here, the AP lines can be connected to a bonding pad to which a chip on film (COF) is attached.

Then, for a narrow bezel, the AP pad is removed from the display panel through a cutting process using a laser after the auto-probe test has been completed. However, the cutting process can leave a sharp, thin edge that is fragile and susceptible to crack formation. Also, the cutting process can invite moisture penetration and the formation of corrosion that can wick into the display area.

Accordingly, in the manufacturing process of a display panel that includes a cutting process to remove the AP pad, there is a need for a display device that simplifies the process, prevents damage to the display panel, prevents crack formation, prevents moisture penetration, and extends a lifespan of the display panel.

### SUMMARY OF THE DISCLOSURE

Embodiments of the present specification provide a display panel using an etching process to etch a portion of the substrate to simplify the manufacturing process, and a display device including the same.

Embodiments of the present specification provide a display panel that is structurally improved to prevent damage caused by an etching process, and a display device including the same.

Embodiments of the present specification provide a display panel that is structurally improved to prevent corrosion development in exposed wiring lines, and a display device including the same.

Objectives of the present specification are not limited to the above-described objectives, and other objectives, which are not described above, will be clearly understood by those skilled in the art from the following description.

A display device according to an embodiment of the present specification can include a substrate disposed in a display area and a non-display area of a display panel, an etch-stop layer disposed on the substrate, a pad part and a bridge disposed spaced apart from each other on the substrate, a first wiring line connected to the bridge on one side and exposed on the other side, and a second wiring line disposed between the pad part and the bridge.

A display device according to an embodiment of the present specification can include a substrate disposed in a display area and a non-display area of a display panel, an etch-stop layer disposed on the substrate, a pad part and a bridge disposed spaced apart from each other on the substrate, a first wiring line connected to the bridge on one side and exposed on the other side, a first connection line connected to the bridge, and a second connection line connected to the pad part, in which the first connection line and the second connection line can be disposed to be spaced apart from each other.

According to the present specification, it is possible to implement process optimization by etching a portion of the substrate through an etching process.

According to the present specification, it is possible to prevent damage to the test lines due to an etching process by arranging the test lines connected to the AP pad to be spaced apart from the etching area formed on the substrate.

According to the present specification, it is possible to prevent the development of corrosion occurring through test lines by use of embodiments of the structure and material for connecting the AP pad and the pad part to which a flexible printed circuit board is attached.

Various useful advantages and effects of the embodiments are not limited to the above-described contents, and other effects, which are not described above, will be clearly understood by those skilled in the art from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a view showing a display device according to an embodiment of the present specification;

FIG. 2 is a cross-sectional view schematically showing the cross-sectional structure of a display area of the display device according to an embodiment of the present specification;

FIG. 3A is a diagram showing a plurality of semi-finished panels arranged on a mother substrate (e.g., an intermediary manufacturing step) according to an embodiment of the present specification;

FIG. 3B is a diagram showing a semi-finished panel separated from the mother substrate according to an embodiment of the present specification;

FIG. 3C is a diagram showing a display panel separated from the semi-finished panel according to an embodiment of the present specification;

FIG. 4A is a cross-sectional view taken along line I-I′ in FIG. 3B according to an embodiment of the present specification;

FIG. 4B is a view illustrating a panel area and an AP pad area separated by a cutting process according to an embodiment of the present specification;

FIG. 5 is a cross-sectional view taken along line II-II′ in FIG. 3C according to an embodiment of the present specification;

FIG. 6 is a view showing another embodiment of a semi-finished panel for forming a display panel according to an embodiment of the present specification;

FIG. 7 is a view showing another embodiment of a semi-finished panel for forming a display panel according to an embodiment of the present specification;

FIGS. 8A to 8C are views illustrating the process of etching the substrate of the semi-finished panel shown in FIG. 7 according to an embodiment of the present specification;

FIG. 9 is a view showing another embodiment of a semi-finished panel for forming a display panel according to an embodiment of the present specification;

FIG. 10 is a view showing a display panel according to an embodiment of the present specification;

FIG. 11A is a cross-sectional view taken along line III-III′ in FIG. 10 according to an embodiment of the present specification;

FIG. 11B is an enlarged view of region A in FIG. 11A according to an embodiment of the present specification;

FIG. 12A is a cross-sectional view showing a display panel with respect to line IV-IV′ in FIG. 10 according to an embodiment of the present specification;

FIG. 12B is a diagram showing a coating layer of the display panel according to an embodiment of the present specification;

FIG. 13 is a cross-sectional view showing a display panel with respect to line IV-IV′ in FIG. 10 according to another embodiment of the present specification;

FIG. 14 is a cross-sectional view showing a display panel with respect to line IV-IV′ in FIG. 10 according to another embodiment of the present specification; and

FIG. 15 is a cross-sectional view showing a display panel with respect to line IV-IV′ in FIG. 10 according to another embodiment of the present specification.

### DETAILED DESCRIPTION OF THE EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted.

The terms such as “comprising,” “including,” “having” and “consisting of” used herein are generally intended to allow other components to be added unless the terms are used with the term “only.” References to the singular shall be construed to include the plural unless expressly stated otherwise.

In interpreting a component, it is interpreted to include an error range even if there is no separate description.

When describing a positional or interconnected relationship between two components, such as “on top of,” “above,” “below,” “next to,” “connect or couple with,” “crossing,” “intersecting” etc., one or more other components can be interposed between them unless “immediately” or “directly” is used.

When describing a temporal contextual relationship is described, such as “after,” “following,” “next to” or “before,” it may not be continuous on a time scale unless “immediately” or “directly” is used.

The terms “first,” “second” and the like can be used to distinguish components from each other, but the functions or structures of the components are not limited by ordinal numbers or component names in front of the components. Also, the term “can” includes all meanings and definitions of the term “may.”

The following embodiments can be combined or associated with each other in whole or in part, and various types of interlocking and driving are technically possible. The embodiments can be implemented independently of each other or together in an interrelated relationship.

Hereinafter, example embodiments of the present disclosure will be described in detail with reference to the accompanying drawings.

As used herein, “a display apparatus” can include a display apparatus in a narrow sense, such as a liquid crystal module (LCM), an organic light-emitting diode (OLED) module, or a quantum dot (QD) module, which includes a display panel and a driver for driving the display panel. It can also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

The display device in this specification can include a display device itself in a narrow sense, an application product including a display in a narrow sense, or even a set device being an end-consumer device.

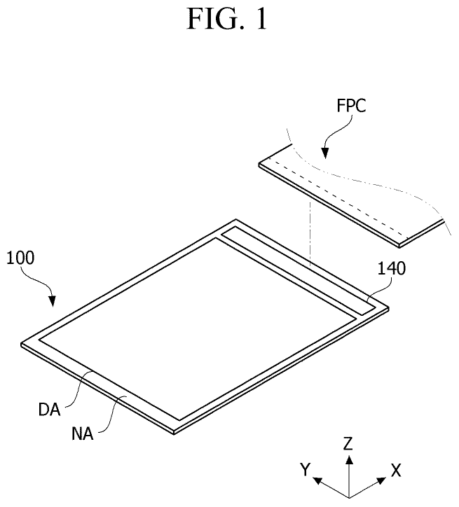

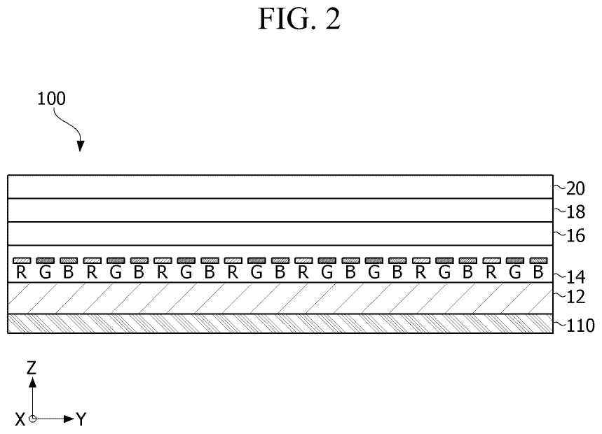

FIG. 1 is a view showing a display device according to an embodiment of the present specification, and FIG. 2 is a cross-sectional view schematically showing the cross-sectional structure of a display area of the display device according to an embodiment of the present specification.

With reference to FIGS. 1 and 2, the display device according to an embodiment of the present specification can include a display panel 100 on which input images are visually reproduced, and a flexible printed circuit (FPC) connected to a pad part 140 of the display panel 100.

The display panel 100 can include a display area DA where an image is displayed and a non-display area NA where an image is not displayed. Here, the display panel 100 can be a panel with a rectangular structure having a width in the X-axis direction, a length in the Y-axis direction, and a thickness in the Z-axis direction. At this time, the width and length of the display panel 100 can be set to various design values depending on the application field of the display device. Additionally, the X-axis direction can mean the width direction, row direction, or horizontal direction; the Y-axis direction can mean the length direction, column direction, or vertical direction; and the Z-axis direction can mean a vertical direction or thickness direction. Further, the X-axis direction, Y-axis direction, and Z-axis direction can be perpendicular to each other, but can also mean different directions that are not perpendicular to each other. Hence, each of the X-axis direction, Y-axis direction, and Z-axis direction can be described as one of a first direction, a second direction, and a third direction. And, the surface extended in the X-axis direction and the Y-axis direction can mean a horizontal surface.

In the display area DA of the display panel 100, data lines, gate lines crossing the data lines, and pixels Px arranged in a matrix form defined by the data lines and the gate lines can be disposed.

Each of the pixels Px includes sub-pixels of different colors for color implementation. The sub-pixels include a red sub-pixel, a green sub-pixel, and a blue sub-pixel. Also, each of the pixels Px can further include a white sub-pixel. In the following description, a pixel can be interpreted as a sub-pixel unless otherwise defined. Additionally, each of sub-pixels can include a pixel circuit.

The pixel circuit can include a light-emitting element, a driving element that supplies a current to the light-emitting element, one or more switch elements that switch the current paths of the driving element and the light-emitting element, and a capacitor that maintains the voltage Vgs between the gate and the source of the driving element.

The light-emitting elements can be implemented in an element structure such as organic light-emitting diode (OLED) display, quantum dot display, and micro light-emitting diode (micro LED) display. In the following description, the light-emitting elements will be described as an OLED structure including an organic compound layer.

The OLED includes an organic compound layer formed between the anode and the cathode. The organic compound layer can include, but not limited to, a hole injection layer (HIL), a hole transport layer (HTL), an emission layer (EML), an electron transport layer (ETL), and an electron injection layer (EIL). When a voltage is applied to the anode electrode and the cathode electrode of the OLED, holes passing through the hole transport layer (HTL) and electrons passing through the electron transport layer (ETL) are moved to the emission layer (EML) to form excitons, thereby emitting visible light in the emission layer (EML).

The display panel driver writes pixel data of the input image to pixels Px. The display panel driver includes a data driver that supplies a data voltage of pixel data to the data lines, and a gate driver that sequentially supplies a gate pulse to the gate lines. The data driver is integrated into a drive IC. The drive IC can be attached to the display panel 100.

The drive IC is connected to the data lines through data output channels and supplies the voltage of the data signal to the data lines. The drive IC includes a timing controller. The timing controller transfers pixel data of the input image received from the host system to the data driver and controls the operation timing of the data driver and the gate driver.

The data driver of the drive IC converts pixel data into a gamma compensation voltage through a digital to analog converter (DAC) to output a data voltage.

The gate driver can include a shift register formed in the circuit layer of the display panel 100 along with the pixel array. The shift register of the gate driver sequentially supplies gate signals to the gate lines under the control of the timing controller. The gate signals can include a scan pulse and an emission control pulse (hereinafter referred to as “EM pulse”). The shift register can include a scan driver that outputs scan pulses and an EM driver that outputs EM pulses.

The host system can be implemented with an application processor. The host system transfers pixel data of the input image to the drive IC. The host system can be connected to the drive IC via a flexible printed circuit (FPC), for example.

In the non-display area NA, various wiring lines and driving circuits can be disposed, and the pad part 140 to which integrated circuits and printed circuits are connected can be disposed.

The flexible printed circuit (FPC) can be formed on a flexible printed circuit board and can be connected to the drive IC through the pad part 140. Here, the drive IC can be disposed on the display panel 100, but without being limited thereto. For example, the drive IC can be disposed on the flexible printed circuit board.

The display panel 100 can be manufactured based on a glass substrate.

With reference to FIG. 2, the display panel 100 can include a circuit layer 12 disposed on a substrate 110, and a light-emitting element layer 14 disposed on the circuit layer 12. In addition, the display panel 100 can include an encapsulation layer 16 disposed on the light-emitting element layer 14, a touch sensor layer 18 formed on the encapsulation layer 16, and a color filter layer 20 disposed on the touch sensor layer 18.

The substrate 110 can be made of an insulating material or a material with flexibility. For example, the substrate 110 can be made of glass, metal, or plastic, without being limited thereto. However, for process simplification, the substrate 110 can be a glass substrate having a specific strength for an etching process.

The circuit layer 12 can include a pixel circuit connected to wirings such as data lines, gate lines, and power lines, and a gate driver connected to the gate lines, or the like. Further, the wirings and circuit elements of the circuit layer 12 can include a plurality of insulating layers, two or more metal layers separated with the insulating layer interposed therebetween, and an active layer including a semiconductor material.

The light-emitting element layer 14 can include a light emitting element driven by a pixel circuit. Further, the light emitting element can include a red light emitting element, a green light emitting element, and a blue light emitting element. In another embodiment, the light-emitting element layer 14 can include a white light emitting element and a color filter. The light emitting elements of the light-emitting element layer 14 can be covered by a protective layer including an organic film and a protective film.

The encapsulation layer 16 covers the light-emitting element layer 14 to seal the circuit layer 12 and the light-emitting element layer 14. Here, the encapsulation layer 16 can have a multi-insulation layer structure in which organic layers and inorganic films are alternately stacked on each other. In this situation, the inorganic film can block penetration of moisture or oxygen. The organic layer flattens or planarizes the surface of the inorganic film. When the organic layer and the inorganic film are stacked in multiple layers, the movement path of moisture or oxygen is longer than that of a single layer, so that penetration of moisture/oxygen affecting the light-emitting element layer 14 can be effectively blocked.

The touch sensor layer 18 can include capacitive touch sensors that sense a touch input based on a change in capacitance before and after touch input. The touch sensor layer 18 can include metal line patterns and insulating films that constitute the capacitance of the touch sensors. The insulating films can insulate the intersections of the metal line patterns and planarize the surface of the touch sensor layer.

On the touch sensor layer 18, a polarizing plate can be bonded. The polarizing plate can improve visibility and contrast ratio by converting polarization of external light reflected by the metal patterns of the circuit layer 12. Here, the polarizing plate can be implemented with a polarizing plate in which a linear polarizing plate and a phase retardation film are bonded together or a circular polarizing plate. Further, a cover glass can be bonded on the polarizing plate.

A color filter layer 20 can be formed on the touch sensor layer 18.

The color filter layer 20 can include red, green, and blue color filters CF. In addition, the color filter layer 20 can further include a black matrix pattern BM. The color filter layer 20 can absorb some wavelengths of light reflected from the circuit layer 12 to serve as a polarizing plate and increase color purity. In an embodiment, the light transmittance of the display panel 100 can be improved and the thickness and flexibility of the display panel 100 can be improved by applying the color filter layer 20 having higher light transmittance than that of the polarizing plate to the display panel. On the color filter layer 20, a cover glass can be bonded.

The color filter layer 20 can include an organic film covering the color filter and the black matrix pattern. An extended portion of the organic film can cover the remaining inorganic film or the substrate 110 in the bezel area BZ, that is, an edge area of the display panel 100.

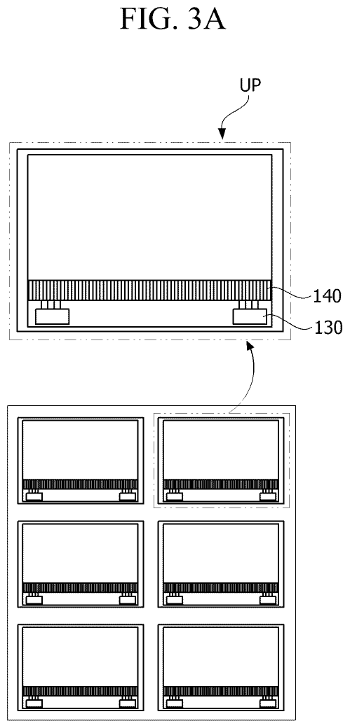

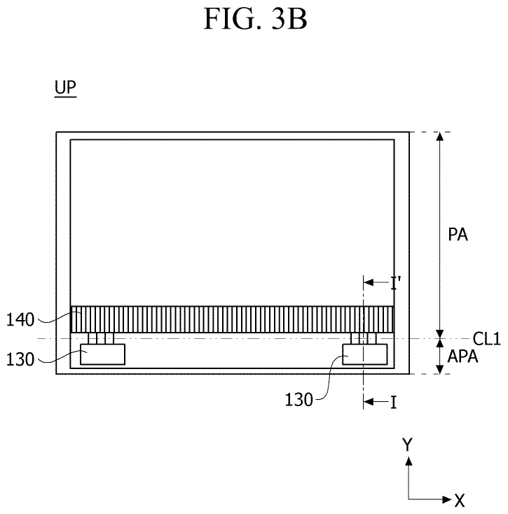

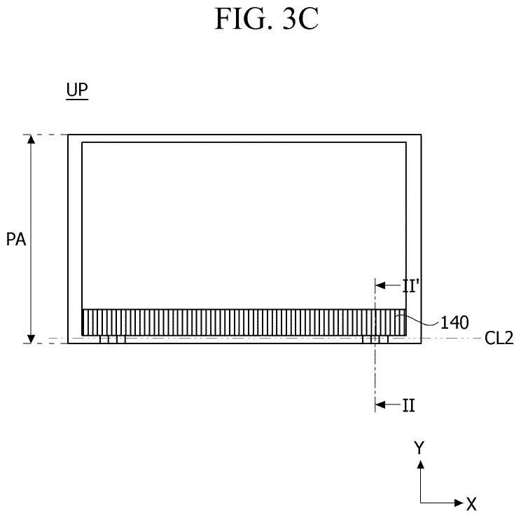

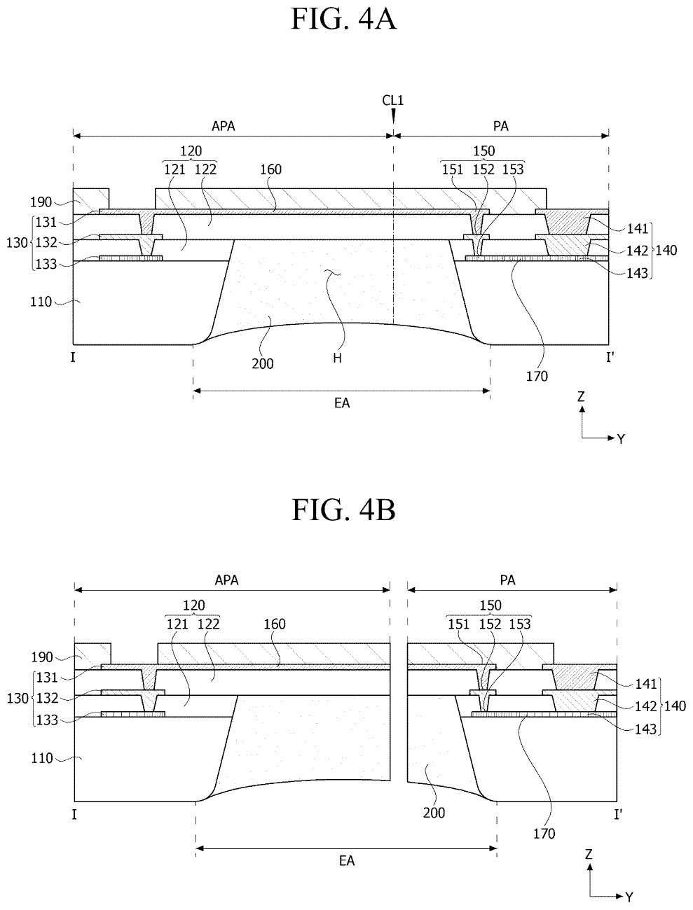

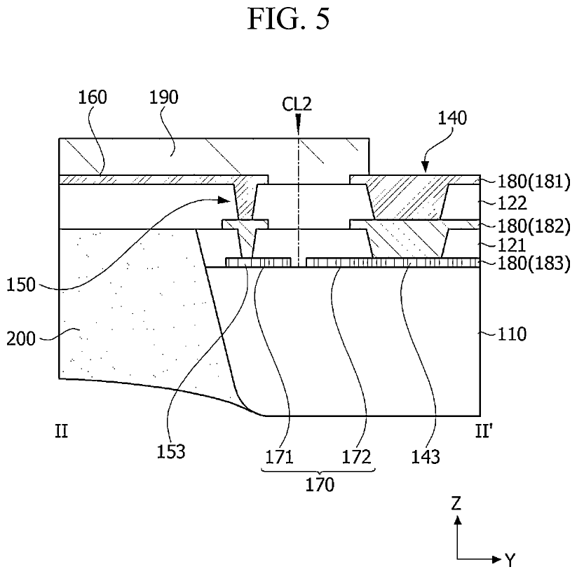

FIGS. 3A-3C illustrate a process of separating a semi-finished panel from a mother substrate and forming a display panel through a cutting process; FIG. 3A is a diagram showing a plurality of semi-finished panels arranged on the mother substrate; FIG. 3B is a diagram showing a semi-finished panel separated from the mother substrate; FIG. 3C is a diagram showing a display panel separated from the semi-finished panel. FIG. 4A is a cross-sectional view taken along line I-I′ in FIG. 3B, and FIG. 4B is a view illustrating a panel area and an AP pad area separated by a cutting process. FIG. 5 is a cross-sectional view taken along line II-II′ in FIG. 3C. Here, the semi-finished panel shown in FIG. 4A can represent a semi-finished panel according to a first embodiment.

With reference to FIGS. 3 to 5, it is possible to complete the display panel 100 used for the display device of the present specification by using an etching process and a laser cutting process.

When performing a cutting process by irradiating a laser along the outer periphery line of the semi-finished panel UP and a first cutting line CL1 without an etching process, since problems such as damage due to a decrease in rigidity at the edge of the substrate 110 and injury due to the edge of the substrate 110 can occur, a separate finishing process such as a grinding process is required for the substrate 110. As a result, the productivity of the display device can decrease due to an increase in the number of processes.

The display device according to an embodiment of the present specification can reduce the sharpness of the side surface of the substrate 110 while maintaining the rigidity of the substrate by using an etching process. Additionally, the display device according to an embodiment of the present specification can form various openings in the substrate by using an etching process (e.g., a perforation line).

The display device according to an embodiment of the present specification enables low-power operation of the production process in terms of production energy reduction through increasing process efficiency by omitting a separate finishing process for the substrate. For example, in the display device according to an embodiment of the present specification, a groove H can be formed through an etching process at a portion of the semi-finished panel UP corresponding to the first cutting line CL1, so that a finishing process for the edge of the substrate can be omitted. Here, the groove H can be formed to have a tapered shape. According to an embodiment, the groove H can be a single, long continuous groove, but embodiments are not limited thereto. For example, according to another embodiment, the groove H can be formed as a plurality of grooves forming a line of perforation holes or depressions.

In addition, for laser cutting along the first cutting line CL1, the semi-finished panel UP includes a groove H corresponding to the first cutting line CL1, so that the cutting process can be carried out easily by using the groove H. Here, the area where the groove H is formed through an etching process can be called the etching area EA. Additionally, the etching area EA can be disposed in correspondence to the first cutting line CL1. Further, the cutting process that irradiates a laser along the first cutting line CL1 can be called a first cutting process.

With reference to FIGS. 3A and 3B, one semi-finished panel UP can be separated from the mother substrate on which a plurality of semi-finished panels UP are implemented. For example, each semi-finished panel UP can be separated by performing a cutting process along the periphery of the semi-finished panel UP. At this time, by performing an etching process along the periphery of the semi-finished panels UP disposed on the mother substrate and then performing a cutting process, the sharpness of the edge of the substrate 110 can be alleviated which can help prevent cracks from forming in the substrate 110. For example, a sharp thin edge can be rather fragile and susceptible to crack formation. Here, the mother substrate can be formed through a process of forming metals corresponding to various electrodes or wiring lines and various insulating films on the substrate. At this time, test lines, AP pads AP, or the other elements can be patterned on the mother substrate.

With reference to FIGS. 3B and 3C, the semi-finished panel UP can include a panel area PA and an AP pad area APA separated from the panel area PA by cutting with respect to the first cutting line CL1. For example, after a test process is performed using the AP pads 130 disposed in the AP pad area APA, a laser irradiated along the first cutting line CL1 can separate the panel area PA and the AP pad area APA (e.g., the AP pad area APA can be cut away from the panel area PA and removed). At this time, since the semi-finished panel UP includes a groove H corresponding to the first cutting line CL1, even if the AP pad area APA is separated from the panel area PA, the sharpness of the edge of the substrate 110 can be reduced.

Then, the laser irradiated along a second cutting line CL2 can cut a connection line 170 disposed in the panel area PA to form the display panel 100 according to embodiments of the present specification. Here, the cutting process of cutting the connection line 170 by irradiating a laser along the second cutting line CL2 can be called a second cutting process.

Therefore, after a semi-finished panel UP can be made by performing an etching process, a cutting process, and a coating process on the mother substrate, the display panel 100 according to embodiments of the present specification can be formed by irradiating a laser to the semi-finished panel UP along the first cutting line CL1 and the second cutting line CL2. Here, through the coating process, a coating layer 200 can be further disposed in the groove H.

With reference to FIG. 4A, the semi-finished panel UP according to an embodiment of the present specification can be divided into a panel area PA and an AP pad area APA with respect to the first cutting line CL1, and can include a groove H disposed in correspondence to the first cutting line CL1. Here, the groove H can be formed through an etching process. Additionally, a coating layer 200 can be disposed in the groove H, without being limited thereto. For example, the coating layer 200 can fill the groove H. According to an embodiment the coating layer 200 can be selectively formed only in the groove H without overlapping other areas of the substrate 110, but embodiments are not limited thereto. For example, according to an embodiment, the coating layer 200 can be formed across an entire rear surface of the substrate 110 and in the groove H.

The semi-finished panel UP according to an embodiment of the present specification can include a substrate 110, an etch-stop layer 120 disposed on the substrate 110, an AP pad 130, a pad part 140, a bridge 150, a test line 160 connecting the AP pad 130 to the bridge 150, a connection line 170 connecting the pad part 140 to the bridge 150, a signal line 180 connected to one side of the pad part 140, and a protective layer 190 disposed on a second etch-stop layer 122 to expose some of the AP pad 130 and the pad part 140. Here, the etch-stop layer 120 can include a first etch-stop layer 121 and a second etch-stop layer 122 disposed on the first etch-stop layer 121. Additionally, the groove H can be formed to penetrate through the substrate 110 and penetrate through the first etch-stop layer 121 through an etching process, and be long along the Y direction in correspondence to the first cutting line CL1. At this time, in the groove H, only a portion of the first etch-stop layer 121 can be etched so that the first etch-stop layer 121 remains in part between the groove H and the second etch-stop layer 122.

In addition, the semi-finished panel UP according to an embodiment of the present specification can further include a coating layer 200 disposed in the groove H formed through an etching process.

The substrate 110 can be a glass substrate having a specific strength. However, without being limited thereto, the substrate 110 can further include a flexible material such as polyimide.

Additionally, as the groove H is formed to expose the upper surface 111 of the substrate 110 through the etching process, the side surface 112 of the substrate 110 can include a rounded edge. Further, the side surface 112 can be formed to have a gentle slope through the etching process. Thereby, the strength of the side surface 112 of the substrate 110 can be improved, and cracks can be prevented. For example, a sharp thin edge can be rather fragile and susceptible to crack formation. Thus, according to an embodiment, a sharp thin edge of the substrate 110 can be removed and rounded.

Even if an etching process is performed on the mother substrate, the etch-stop layer 120 can prevent the test lines 160 or the other elements from being damaged by the etchant. Hence, the etch-stop layer 120 can be disposed in correspondence to the etching area and can be made of a material different from that of the substrate 110.

The first etch-stop layer 121 can be thinner than the second etch-stop layer 122. In consideration of the depth of the groove H formed by an etching process, the first etch-stop layer 121 can be formed to be thinner than the second etch-stop layer 122.

The first etch-stop layer 121 and the second etch-stop layer 122 can be made of different materials. For example, the chemical resistance of the second etch-stop layer 122 can be higher than that of the first etch-stop layer 121. Here, chemical resistance can mean the degree to which it does not react with the etchant. Hence, a layer with high chemical resistance can be relatively less etched.

The first etch-stop layer 121 can be the same layer as the interlayer insulating layer formed in the display area DA, and the second etch-stop layer 122 can be the same layer as the planarization layer formed in the display area DA, but without being limited thereto. For example, the first etch-stop layer 121 and the second etch-stop layer 122 can be composed of various organic insulating layers and metal layers in the display area DA. Additionally, the first etch-stop layer 121 and the second etch-stop layer 122 can each be composed of a plurality of layers.

The first etch-stop layer 121 is disposed on the substrate 110, and a portion of the first etch-stop layer 121 is etched away through an etching process to form a portion of the groove H.

The first etch-stop layer 121 can include a single-layer or multi-layer inorganic insulating material. Also, the first etch-stop layer 121 can react relatively better to the etchant than the second etch-stop layer 122.

The second etch-stop layer 122 can be disposed on the first etch-stop layer 121 so that a portion thereof can overlap with the groove H.

The second etch-stop layer 122 can include a single-layer or multi-layer organic insulating material. For example, the second etch-stop layer 122 can include an organic material such as polyimide. Hence, the second etch-stop layer 122 being an organic material can have greater chemical resistance to the etchant such as hydrofluoric acid. That is, the second etch-stop layer 122 can be less etched by the etchant than the first etch-stop layer 121.

The AP pad 130 can be placed in the AP pad area APA and can be used for auto-probe testing. Additionally, the AP pad 130 can be electrically connected to the bridge 150 through the test line 160.

The AP pad 130 can be formed to penetrate through both of the first etch-stop layer 121 and the second etch-stop layer 122.

The AP pad 130 can include a first AP pad layer 131 disposed on the second etch-stop layer 122, and a second AP pad layer 132 disposed on the first etch-stop layer 121. Additionally, the first AP pad layer 131 and the second AP pad layer 132 can be electrically connected to each other through a contact hole formed in the second etch-stop layer 122. Here, the AP pad 130 is illustrated as being composed of the first AP pad layer 131 and the second AP pad layer 132, but without being limited thereto. For example, the AP pad 130 can be composed of only the first AP pad layer 131.

The first AP pad layer 131 and the second AP pad layer 132 can be made of the same material, but embodiments are not limited thereto. For example, according to another embodiment, the first AP pad layer 131 and the second AP pad layer 132 can be made of different materials. For example, each of the first AP pad layer 131 and the second AP pad layer 132 can include titanium (Ti) and aluminum (Al), and can be formed in a three-layer structure (e.g., the first AP pad layer 131 can have three layers, and the second AP pad layer 132 can have three layers).

The first AP pad layer 131 can be electrically connected to the test line 160, and a portion thereof can be exposed for the test process.

The AP pad 130 can further include a third AP pad layer 133 disposed on the substrate 110. At this time, the third AP pad layer 133 can be disposed to overlap the first AP pad layer 131 and the second AP pad layer 132.

The third AP pad layer 133 can be electrically connected to the second AP pad layer 132 through a contact hole formed in the first etch-stop layer 121. For example, the AP pad 130 can be a triple layer pad.

The third AP pad layer 133 can be made of a material different from that of the first AP pad layer 131. For example, the third AP pad layer 133 can include molybdenum (Mo) being resistant to corrosion.

The third AP pad layer 133 can be formed together with the connection line 170 in a process of forming the connection line 170. At this time, the third AP pad layer 132 can be arranged to be spaced apart from the connection line 170. For example, the groove H can be disposed between the third AP pad layer 132 and the connection line 170 with respect to the Y direction, so that the third AP pad layer 132 can be structurally spaced apart from the connection line 170.

The pad part 140 can be disposed in the panel area PA, and one side thereof can be connected to the connection line 170 and the other side can be connected to the signal line 180. Additionally, a flexible printed circuit board can be attached to the pad part 140.

The pad part 140 can be formed to penetrate through both of the first etch-stop layer 121 and the second etch-stop layer 122.

The pad part 140 can include a first pad layer 141 disposed on the second etch-stop layer 122, a second pad layer 142 disposed on the first etch-stop layer 121, and a third pad layer 143 disposed on the substrate 110. For example, the pad part 140 can be a triple layer pad part. At this time, the first pad layer 141, the second pad layer 142, and the third pad layer 143 can overlap with each other in the Z direction. In addition, the first pad layer 141 and the second pad layer 142 can be electrically connected through a contact hole formed in the second etch-stop layer 122, and the third pad layer 143 can be electrically connected to the second pad layer 142 through a contact hole formed in the first etch-stop layer 121.

The first pad layer 141 and the second pad layer 142 can be made of the same material, but embodiments are not limited thereto and the first pad layer 141 and the second pad layer 142 can be made of different materials. For example, the first pad layer 141 and the second pad layer 142 can include titanium (Ti) and aluminum (Al), and can be formed in a three-layer structure.

The first pad layer 141 can be electrically connected to a first signal line 181 among the signal lines 180, and a portion thereof can be exposed for coupling with a flexible printed circuit board (e.g., see FIG. 5).

The second pad layer 142 can be electrically connected to a second signal line 182 among the signal lines 180.

The third pad layer 143 can be electrically connected to a third signal line 183 among the signal lines 180.

The third pad layer 143 can be made of a material different from that of the first pad layer 141, and the third pad layer 143 can be formed together with the connection lines 170 in the process of forming the connection lines 170, but without being limited thereto. For example, in consideration of the resistance of the pad part 140, the third pad layer 143 can be made of the same material as the first pad layer 141. Consequently, the third pad layer 143 can be made of a material different from that of the connection line 170.

The bridge 150 is disposed in the panel area PA.

The bridge 150 can be disposed between the AP pad 130 and the pad part 140 for an electrical connection relationship. The bridge 150 can be electrically connected to the AP pad 130 through the test line 160 and electrically connected to the pad part 140 through the connection line 170. For example, the bridge 150 can be electrically connected between the test line 160 and the pad part 140.

The bridge 150 can be formed to penetrate through both of the first etch-stop layer 121 and the second etch-stop layer 122.

The bridge 150 can include a first bridge layer 151 disposed on the second etch-stop layer 122, a second bridge layer 152 disposed on the first etch-stop layer 121, and a third bridge layer 153 disposed on the substrate 110. At this time, the first bridge layer 151, the second bridge layer 152, and the third bridge layer 153 can overlap with each other in the Z direction. In addition, the first bridge layer 151 and the second bridge layer 152 can be electrically connected with each other through a contact hole formed in the second etch-stop layer 122, and the third bridge layer 153 can be electrically connected to the second bridge layer 152 through a contact hole formed in the first etch-stop layer 121.

The first bridge layer 151 and the second bridge layer 152 can be made of the same material, but embodiments are not limited thereto and the first bridge layer 151 and the second bridge layer 152 can be made of different materials. For example, the first bridge layer 151 and the second bridge layer 152 can include titanium (Ti) and aluminum (Al), and can be formed in a three-layer structure or as a type of triple layer bridge.

The first bridge layer 151 can be electrically connected to the test line 160.

The third bridge layer 153 can be formed of a material different from that of the first bridge layer 151 and the second bridge layer 152. For example, the third bridge layer 153 can include molybdenum (Mo) being resistant to corrosion.

The third bridge layer 153 can be formed together with the connection line 170 in the process of forming the connection line 170, and can be made of the same material as the connection line 170.

The test line 160 can electrically connect the AP pad 130 with the bridge 150.

The test line 160 can be arranged to be spaced apart from the groove H to prevent damage due to an etching process. For example, the test line 160 can be disposed on the second etch-stop layer 122 or on the protective layer 190.

When the test line 160 is disposed on the second etch-stop layer 122, it can be made of the same material as the first AP pad layer 131 or the first bridge layer 151 in consideration of process efficiency. For example, the test line 160 can be made of a material containing titanium (Ti) and aluminum (Al), and can be formed in a three-layer structure.

When the test line 160 is disposed on the protective layer 190, it can be made of the same material as the first AP pad layer 131 or the first bridge layer 151 in consideration of the resistance of the test line 160, but without being limited thereto. For example, the test line 160 can be made of a material containing molybdenum (Mo) being resistant to corrosion.

The connection line 170 can electrically connect the bridge 150 and the pad part 140. For example, the connection line 170 can connect the first pad layer 141 and the first bridge layer 151, can connect the second pad layer 142 and the second bridge layer 152, or can connect the third pad layer 143 and the third bridge layer 153.

In consideration that the test line 160 can be exposed to the outside due to the first cutting process to cause corrosion and the corrosion can develop along the test line 160, the connection line 170 can be disposed on the substrate 110 to connect the third pad layer 143 and the third bridge layer 153. At this time, the connection line 170 can be formed together with the third pad layer 143 through the same process. Consequently, the connection line 170, the third pad layer 143, and the third bridge layer 153 can be formed integrally with each other as a same wire or a same metal layer.

The signal lines 180 are connected to the pad part 140, and can include a plurality of data lines and a plurality of gate lines (e.g., FIG. 5). Additionally, the signal lines 180 can further include power lines such as a plurality of driving voltage lines and a plurality of reference voltage lines.

The signal lines 180 can include a first signal line 181 disposed on the second etch-stop layer 122, a second signal line 182 disposed on the first etch-stop layer 121, and a third signal line 183 disposed on the substrate 110.

In consideration of the efficiency of the manufacturing process and the resistance of the signal lines 180, the first signal line 181 can be made of the same material as the first pad layer 141, the second signal wire 182 can be made of the same material as the second pad layer 142, and the third signal line 183 can be made of the same material as the third pad layer 143.

The protective layer 190 can be disposed on the second etch-stop layer 122 to expose a portion of the AP pad 130 and expose a portion of the pad part 140, and can cover the test line 160.

The protective layer 190 can include a single-layer or multi-layer organic insulating material. For example, the second etch-stop layer 122 can include an organic material such as polyimide. Additionally, the protective layer 190 can be the same layer as the planarization layer formed in the display area DA, but without being limited thereto.

The coating layer 200 can be disposed in the groove H, but without being limited thereto. For example, the coating layer 200 can be disposed on the lower surface of the substrate 110, that is, on the surface opposite to the surface in contact with the first etch-stop layer 121.

The coating layer 200 can be made of an organic material containing a polyester-based polymer or an acrylic-based polymer.

With reference to FIG. 4B, as the test line 160 is exposed to the outside due to the first cutting process, corrosion can occur in the exposed test line 160. Then, the corrosion can develop along the test line 160 to cause defects in the display panel 100. For example, corrosion can wick through the test line 160 toward in an interior of the display panel 100.

Accordingly, the display panel 100 according to an embodiment of the present specification can prevent corrosion development in the test line 160 by providing examples of a corrosion prevention structure and material disposed between the AP pad 130 and the pad part 140.

The display panel 100 according to an embodiment of the present specification can prevent corrosion development by disposing the bridge 150 between the AP pad 130 and the pad part 140, in which the bridge 150 can be made up of multiple layers that respond to corrosion differently. In other words, the bridge 150 can act as a type of corrosion stopper which can halt the spread of corrosion and protect the interior of the display panel 100.

Also, bridge 150 can prevent corrosion development along the test line 160 by increasing the length of a path through which corrosion develops.

In addition, corrosion development can be prevented by forming at least one of the first bridge layer 151, the second bridge layer 152, and the third bridge layer 153 by using a material that is resistant to corrosion. For example, the third bridge layer 153 can be made of molybdenum (Mo), which is resistant to corrosion to prevent corrosion development.

In addition, corrosion development can be prevented by making the material of the connection line 170 the same as that of the third bridge layer 153.

In addition, as shown in FIG. 5, corrosion development can be completely prevented in structure by cutting the connecting line 170 through the second cutting process. At this time, the connection line 170 can include a first connection line 171 and a second connection line 172 separated by the second cutting process. Here, the first connection line 171 can be connected to the third bridge layer 153, the second connection line 172 can be connected to the third pad layer 143, and the first connection line 171 and the second connection line 172 can be spaced apart from each other. For example, during different steps of the manufacturing process, the development of corrosion can be contained on one side of the bridge, and then, the threat of the corrosion can be eliminated by cutting off the bridge at a subsequent processing step by disconnecting a portion of the connecting line 170 by a laser.

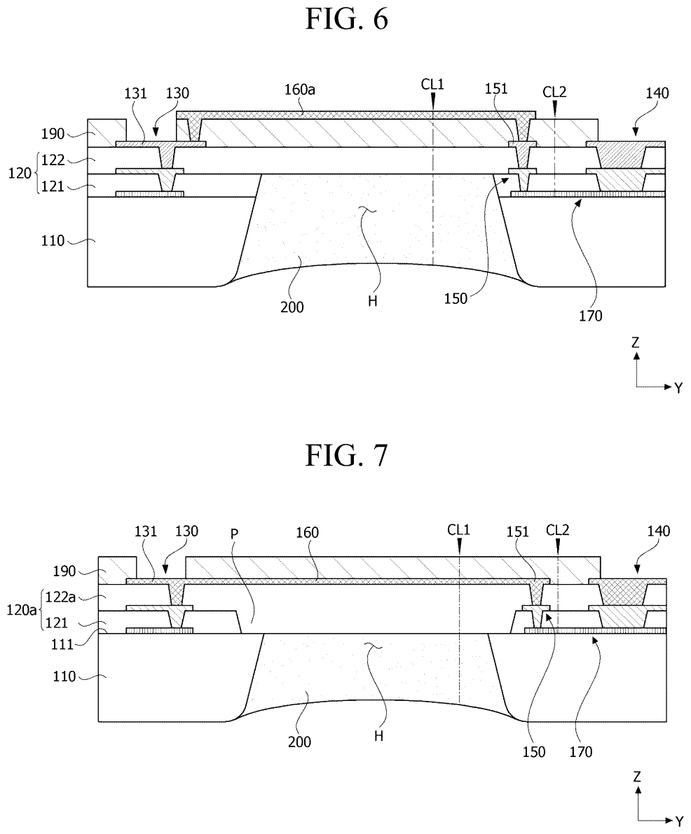

FIG. 6 is a view showing another embodiment of a semi-finished panel for forming a display panel according to an embodiment of the present specification. The semi-finished panel shown in FIG. 6 can represent a semi-finished panel according to a second embodiment.

When comparing the semi-finished panel UP according to the first embodiment and the semi-finished panel UP according to the second embodiment with reference to FIG. 4A and FIG. 6, there is a difference in that the test line 160a of the semi-finished panel UP according to the second embodiment is disposed farther apart from the groove H (e.g., 160a is located higher up) than the test line 160 of the semi-finished panel UP according to the first embodiment.

With reference to FIG. 6, the semi-finished panel UP according to the second embodiment can include a substrate 110, an etch-stop layer 120 disposed on the substrate 110, an AP pad 130, a pad part 140, a bridge 150, a test line 160a connecting the AP pad 130 and the bridge 150, a connection line 170 connecting the pad part 140 and the bridge 150, a signal line 180 connected to one side of the pad part 140, and a protective layer 190 disposed on a second etch-stop layer 122 to expose a portion of the AP pad 130 and the pad part 140.

In addition, the semi-finished panel UP according to the second embodiment can further include a coating layer 200 disposed in the groove H.

The test line 160a can be disposed on the protective layer 190 to electrically connect the AP pad 130 with the bridge 150. Accordingly, the test line 160a is arranged to be spaced farther away from the groove H than the test line 160 of the semi-finished panel UP according to the first embodiment, thereby further reducing the possibility of damage due to etching.

One side of the test line 160a can be electrically connected to the first AP pad layer 131 through a contact hole formed in the protective layer 190, and the other side thereof can be electrically connected to the first bridge layer 151 through a contact hole formed in the protective layer 190.

The test line 160a can be made of the same material as the first AP pad layer 131 or the first bridge layer 151. For example, the test line 160a can be made of a material containing titanium (Ti) and aluminum (Al), and can be formed in a three-layer structure.

The test line 160a can be formed together with the anode electrode formed in the display area DA in the process of forming the anode electrode, but without being limited thereto. For example, the test line 160a can be made of a material containing molybdenum (Mo) being resistant to corrosion.

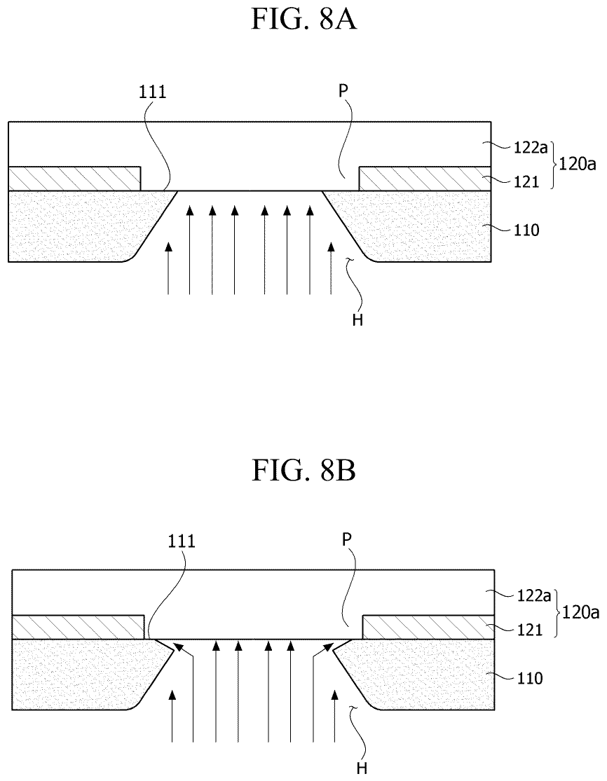

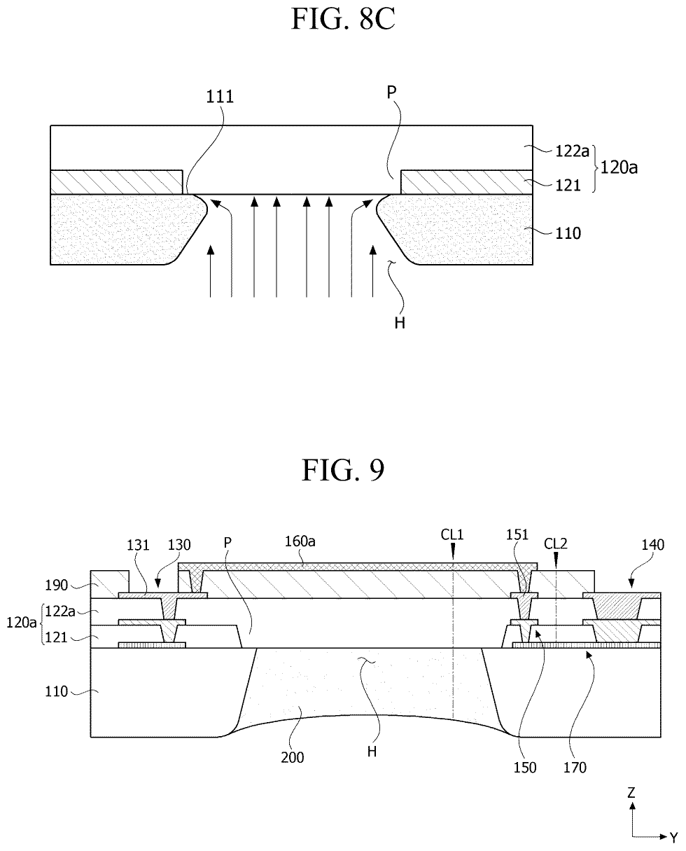

FIG. 7 is a view showing another embodiment of a semi-finished panel for forming a display panel according to an embodiment of the present specification, and the semi-finished panel shown in FIG. 7 can represent a semi-finished panel according to a third embodiment. FIGS. 8A to 8C are views illustrating the process of etching the substrate of the semi-finished panel shown in FIG. 7.

When comparing the semi-finished panel UP according to the first embodiment and the semi-finished panel UP according to the third embodiment with reference to FIG. 4A and FIG. 7, there is a difference in that a portion of the second etch-stop layer 122a of the semi-finished panel UP according to the third embodiment is in contact with the substrate 110 around the groove H. For example, the groove H in FIG. 7 is not as deep as the groove H in FIG. 4A and in FIG. 6, and a portion of the second etch-stop layer 122a is thicker.

With reference to FIG. 7, the semi-finished panel UP according to the third embodiment can include a substrate 110, an etch-stop layer 120a disposed on the substrate 110, an AP pad 130, a pad part 140, a bridge 150, a test line 160 connecting the AP pad 130 and the bridge 150, a connection line 170 connecting the pad part 140 and the bridge 150, a signal line 180 connected to one side of the pad part 140, and a protective layer 190 disposed on a second etch-stop layer 122a to expose a portion of the AP pad 130 and to expose a portion of the pad part 140.

In addition, the semi-finished panel UP according to the third embodiment can further include a coating layer 200 disposed in the groove H.

The second etch-stop layer 122a can include a protrusion P that contacts the substrate 110 around the groove H (e.g., a portion where the second etch-stop layer 122a is thicker). Here, the protrusion P is disposed to overlap with the first etch-stop layer 121 in the Y direction to separate the first etch-stop layer 121 apart from the groove H. At this time, the protrusion P can protrude from the second etch-stop layer 122a in a downward direction toward the substrate 110. Consequently, the etchant can not come into contact with the first etch-stop layer 121 due to the protrusion P.

With reference to FIG. 8A, a mask pattern can be formed on the lower portion of the substrate 110 to expose the etching area EA. At this time, the first etch-stop layer 121 and a portion of the second etch-stop layer 122a can be disposed on the upper portion of the substrate 110, and an end portion of the protrusion P can be in contact with the substrate 110. Consequently, a groove H can be formed in a region of the substrate 110 corresponding to the etching area EA.

With reference to FIG. 8B, when the etching area EA of the substrate 110 is etched, the lower surface of the second etch-stop layer 122a, that is, a portion of the protrusion P, can be exposed to the etchant. The second etch-stop layer 122a has strong chemical resistance to the etchant, but has relatively weak adhesion to the substrate 110. Hence, as etching progresses, the adhesion between the substrate 110 and the protrusion P can weaken and start to peel away, allowing the etchant to flow into the region where the protrusion P and the substrate 110 are in contact (e.g., some of the etchant can seep between second etch-stop layer 122a and the substrate 110). As a result, the etchant can etch a portion of the upper surface 111 of the substrate 110.

Additionally, even if the mask pattern is disposed in contact with a lower portion of the substrate 110, the etchant can penetrate between the mask pattern and the substrate 110 to etch the lower edge of the substrate 110.

With reference to FIG. 8C, the protrusion P of the second etch-stop layer 122a can gradually become spaced apart from the substrate 110 as the etching time elapses. At this time, although the second etch-stop layer 122a has relatively strong chemical resistance, a portion of the protrusion P can be physically torn off depending on the etching conditions. For example, when the flow rate or fluid pressure of the etchant increases, a portion of the lower surface of the protrusion P corresponding to the groove H can be torn off and removed. Additionally, depending on the type of organic material forming the second etch-stop layer 122a, if the etching time is prolonged, a portion of the lower surface of the protrusion P can be dissolved in the etchant.

Consequently, the edge of the substrate 110 forming the groove H can be rounded through the etching process, so that sharpness in the edge region of the substrate 110 can be alleviated thereby preventing cracks from forming at or near the edge region of the substrate 110, which can prevent defects and improve the lifespan of the display device.

FIG. 9 is a view showing another embodiment of a semi-finished panel for forming a display panel according to an embodiment of the present specification. The semi-finished panel shown in FIG. 9 can represent a semi-finished panel according to a fourth embodiment.

When comparing the semi-finished panel UP according to the first embodiment and the semi-finished panel UP according to the fourth embodiment with reference to FIG. 4A and FIG. 9, there is a difference in that the test line 160a of the semi-finished panel UP according to the fourth embodiment is arranged to be spaced farther away from (e.g., higher up) the groove H than the test line 160 of the semi-finished panel UP according to the first embodiment, and a portion of the second etch-stop layer 122a of the semi-finished panel UP according to the fourth embodiment is in contact with the substrate 110 around the groove H (e.g., the second etch-stop layer 122a includes the protrusion P).

With reference to FIG. 9, the semi-finished panel UP according to the fourth embodiment can include a substrate 110, an etch-stop layer 120a disposed on the substrate 110, an AP pad 130, a pad part 140, a bridge 150, a test line 160a connecting the AP pad 130 and the bridge 150, a connection line 170 connecting the pad part 140 and the bridge 150, a signal line 180 connected to one side of the pad part 140, and a protective layer 190 disposed on a second etch-stop layer 122a to expose a portion of the AP pad 130 and the pad part 140.

In addition, the semi-finished panel UP according to the fourth embodiment can further include a coating layer 200 disposed in the groove H.

The second etch-stop layer 122a can include a protrusion P that contacts the substrate 110 around the groove H. Hence, the etchant can not come into contact with the first etch-stop layer 121 due to the protrusion P.

The test line 160a can be disposed on the protective layer 190 to electrically connect the AP pad 130 and the bridge 150. Consequently, the test line 160a can be arranged to be spaced farther away from the groove H than the test line 160 of the semi-finished panel UP according to the first embodiment, thereby further reducing the possibility of damage due to etching (e.g., FIG. 9 includes both the extra spacing for test line 160a from FIG. 6 and the protrusion P for the second etch-stop layer 122a from FIG. 7).

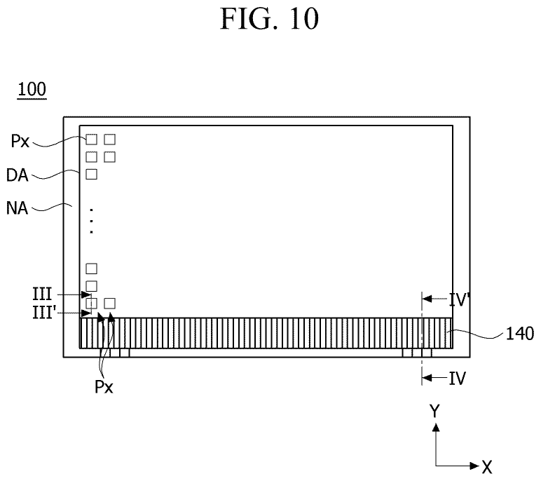

FIG. 10 is a view showing a display panel according to an embodiment of the present specification.

With reference to FIG. 10, the display panel 100 can include a display area DA where an image is displayed and a non-display area NA where an image is not displayed.

The display area DA of the display panel 100 can include data lines, gate lines crossing the data lines, and pixels Px arranged in a matrix form defined by the data lines and the gate lines.

In the non-display area NA, various lines and driving circuits can be disposed, and a pad part 140 to which integrated circuits and printed circuits are connected can be disposed.

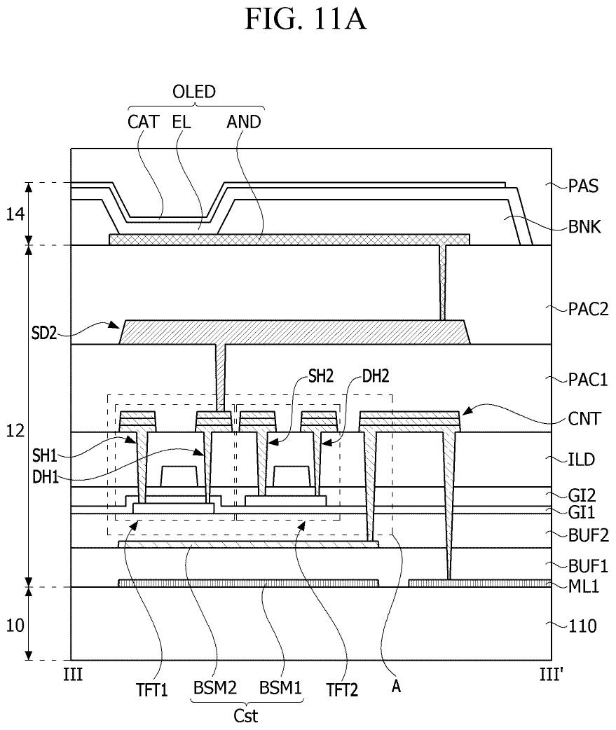

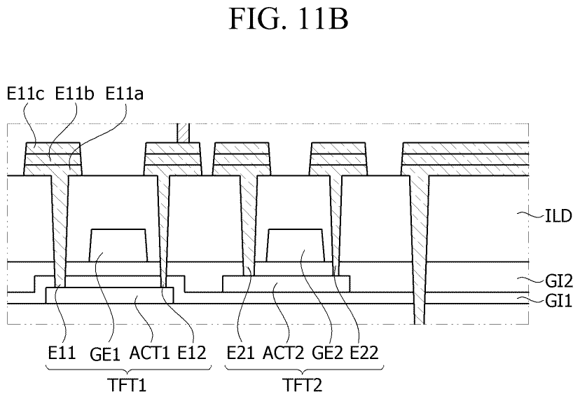

FIG. 11A is a cross-sectional view taken along line III-III′ in FIG. 10 according to an embodiment of the present disclosure, and FIG. 11B is an enlarged view of region A in FIG. 11A according to an embodiment of the present disclosure.

With reference to FIGS. 11A and 11B, in the display area DA, a first transistor TFT1 and a second transistor TFT2 can be disposed on the substrate 110, and a light-emitting element OLED can be disposed on a planarization layer PAC2.

A first light shield layer BSM1 and a first metal layer ML1 can be disposed on the substrate 110.

The first light shield layer BSM1 can include molybdenum and/or aluminum. The first light shield layer BSM1 can block light incident to the first semiconductor layer ACT1 or the second semiconductor layer ACT2. Here, the first light shield layer BSM1 can overlap with the first semiconductor layer ACT1 or the second semiconductor layer ACT2 in the Z direction.

The first metal layer ML1 can be disposed to be spaced apart from the first light shield layer BSM1 and can be formed together with the first light shield layer BSM1 in a process of forming the first light shield layer BSM1. Additionally, the first metal layer ML1 can be electrically connected to the third pad layer 143 of the pad part 140.

The multi-buffer layer BUF1 can delay the diffusion of moisture or oxygen that has penetrated the substrate 110, and can be formed by alternately stacking silicon nitride (SiNx) and silicon oxide (SiOx) at least once.

A second light shield layer BSM2 can be disposed on the multi-buffer layer BUF1. The second light shield layer BSM2 can include molybdenum and/or aluminum. The second light shield layer BSM2 can block light incident to the first semiconductor layer ACT1 or the second semiconductor layer ACT2. The second light shield layer BSM2 can be disposed to overlap with the first light shield layer BSM1 in the Z direction, more effectively blocking light incident to the first semiconductor layer ACT1 or the second semiconductor layer ACT2.

The active buffer layer BUF2 can protect the first semiconductor layer ACT1 and can serve to block various types of defects or outgassing coming from the substrate 110. Here, the active buffer layer BUF2 can be made of a-Si, silicon nitride (SiNx), or silicon oxide (SiOx).

The first semiconductor layer ACT1 of the first transistor TFT1 can be made of a polycrystalline semiconductor layer, and the first semiconductor layer ACT1 can include a channel region, a source region, and a drain region.

A first gate electrode GE1 can be disposed on the upper gate insulating layer GI2 to overlap with the first semiconductor layer ACT1. Here, the upper gate insulating layer GI2 can be disposed on a lower gate insulating layer GI1.

The second transistor TFT2 can be disposed on the lower gate insulating layer GI1. An upper gate insulating layer GI2 can be disposed on the second semiconductor layer ACT2 to insulate the second gate electrode GE2 from the second semiconductor layer ACT2.

An interlayer insulating layer ILD can be disposed on the first gate electrode GE1 and the second gate electrode GE2. The first gate electrode GE1 and the second gate electrode GE2 can be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto.

After the interlayer insulating layer ILD is disposed, a first source contact hole SH1 and a first drain contact hole DH1 can be formed respectively in correspondence to the source region and drain region of the first transistor TFT1, and a second source contact hole SH2 and a second drain contact hole DH2 can be formed respectively in correspondence to the source region and drain region of the second transistor TFT2.

The first source contact hole SH1 and the first drain contact hole DH1 can be a hole formed continuously from the interlayer insulating layer ILD to the lower gate insulating layer GI1, and the second source contact hole SH2 and the second drain contact hole DH2 can also be formed continuously from the interlayer insulating layer ILD to the upper gate insulating layer GI2 in the second transistor TFT2.

The first source electrode E11 and the first drain electrode E12 corresponding to the first transistor TFT1, and the second source electrode E21 and the second drain electrode E22 corresponding to the second transistor TFT2 can be formed simultaneously. Thereby, the number of processes for forming the source and drain electrodes of each of the first transistor TFT1 and the second transistor TFT2 can be reduced.

The first source and drain electrodes E11 and E12 and the second source and drain electrodes E21 and E22 can be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto.

The first source and drain electrodes E11 and E12 and the second source and drain electrodes E21 and E22 can be made of a three-layer structure, e.g., the first source electrode E11 can be composed of a first layer E11a made of Ti, a second layer E11b made of Al, and a third layer E11c made of Ti, and the other source and drain electrodes can have the same structure.

A storage capacitor Cst can be disposed between the first transistor TFT1 and the second transistor TFT2. According to an embodiment, the storage capacitor Cst can be formed using the first light shield layer BSM1 and second light shield layer BSM2. For example, the second light shield layer BSM2 can be electrically connected to the pixel circuit through a storage supply line CNT. However, the structure of the storage capacitor Cst is not necessarily limited to this and can be formed in various forms by using two different metal layers.

The storage supply line CNT can be made of the same material as, on the same plane as, the first source and drain electrodes E11 and E12 and the second source and drain electrodes E21 and E22, and thus the storage supply line CNT can be formed simultaneously with the first source and drain electrodes E11 and E12 and the second source and drain electrodes E21 and E22 by using the same mask process.

A first planarization layer PAC1 can be formed on the first source and drain electrodes E11 and E12, the second source and drain electrodes E21 and E22, and the storage supply line CNT. Specifically, the first planarization layer PAC1 can be disposed by applying a full coating of an organic insulating material such as acrylic resin on the first source and drain electrodes E11 and E12, the second source and drain electrodes E21 and E22, and the storage supply line CNT.

After disposing the first planarization layer PAC1, a contact hole can be formed through a photolithography process to expose the first source electrode E11 or first drain electrode E12 of the first transistor TFT1. A connection electrode SD2 can be disposed in the contact hole region exposing the first drain electrode E12 by using a material made of Mo, Ti, Cu, AlNd, Al, Cr, or an alloy thereof.

A second planarization layer PAC2 can be disposed on the connection electrode SD2. Then, a contact hole exposing the connection electrode SD2 can be formed in the second planarization layer PAC2 to dispose a light-emitting element OLED connected to the first transistor TFT1. The connection electrode SD2 can be formed with a plurality of layer structures in a manner identical to the first source and drain electrodes E11 and E12.

The light-emitting element OLED can include an anode electrode AND connected to the first drain electrode E12 of the first transistor TFT1, at least one light-emitting stack EL formed on the anode electrode AND, and a cathode electrode CAT formed on the light-emitting stack EL.

The light-emitting stack EL can include a hole injection layer, a hole transport layer, an emission layer, an electron transport layer, and an electron injection layer; in a tandem structure where a plurality of emission layers overlap, a charge generation layer can be additionally disposed between the emission layers. In the situation of the emission layer, there can be situations where individual sub-pixels emit different colors.

The anode electrode AND can be connected to the connection electrode SD2 exposed through a contact hole penetrating the second planarization layer PAC2. The anode electrode AND can be formed in a multi-layer structure including a transparent conductive film and an opaque conductive film with high reflection efficiency. The transparent conductive film can be made of a material with a relatively high work function value such as indium-tin-oxide (ITO) or indium-zinc-oxide (IZO), and the opaque conductive film can be formed in a single-layer or multi-layer structure containing Al, Ag, Cu, Pb, Mo, Ti, or an alloy thereof.

For example, the anode electrode AND can be formed in a structure where a transparent conductive film, an opaque conductive film, and a transparent conductive film are stacked in sequence, or can be formed in a three-layer structure like the first source and drain electrodes E11 and E12.

The anode electrode AND can be disposed on the second planarization layer PAC2 to overlap not only the emission area provided by the bank BNK but also the pixel circuit area where the first and second transistors TFT1 and TFT2 and the storage capacitor Cst are arranged, increasing the area of emission.

The light-emitting stack EL can be formed by stacking a hole transport layer, an organic emission layer, and an electron transport layer in that order or in the reverse order on the anode electrode AND. In addition, the light-emitting stack EL can further include a charge generation layer, and include first and second light-emitting stacks facing each other with a charge generation layer interposed therebetween.

The bank BNK can be formed to expose the anode electrode AND. This bank BNK can be made of an organic material such as photo acryl, and can be a translucent material, but without being limited thereto. For example, the bank BNK can be made of an opaque material to prevent light interference between sub-pixels.

The cathode electrode CAT can be formed on the upper surface of the light-emitting stack EL to face the anode electrode AND with the light-emitting stack EL interposed therebetween. When applied to an organic light-emitting display device of a front-emitting type, the cathode electrode CAT can be provided as a transparent conductive film made of thinned indium-tin-oxide (ITO), indium-zinc-oxide (IZO), or magnesium-silver (Mg—Ag).

An encapsulation portion PAS can be formed on the cathode electrode CAT to protect the light-emitting element OLED. In the light-emitting element OLED, owing to the organic nature of the light-emitting stack EL, a dark spot or pixel shrinkage can occur due to reaction with external moisture or oxygen. To prevent this, the encapsulation portion PAS can be disposed on the cathode electrode CAT.

The encapsulation portion PAS can be composed of a first inorganic insulating layer, a foreign material compensation layer, and a second inorganic insulating layer 173.

The touch sensor layer 18 and the color filter layer 20 can be further disposed on the top of the encapsulation portion PAS, but without being limited thereto.

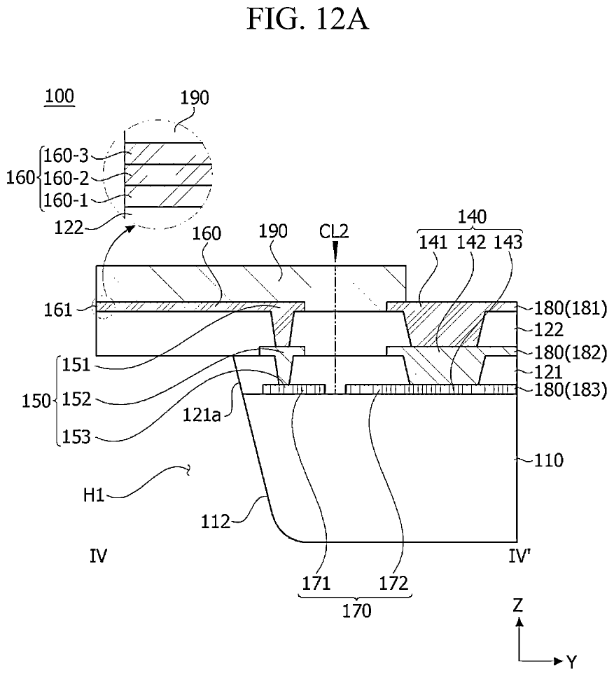

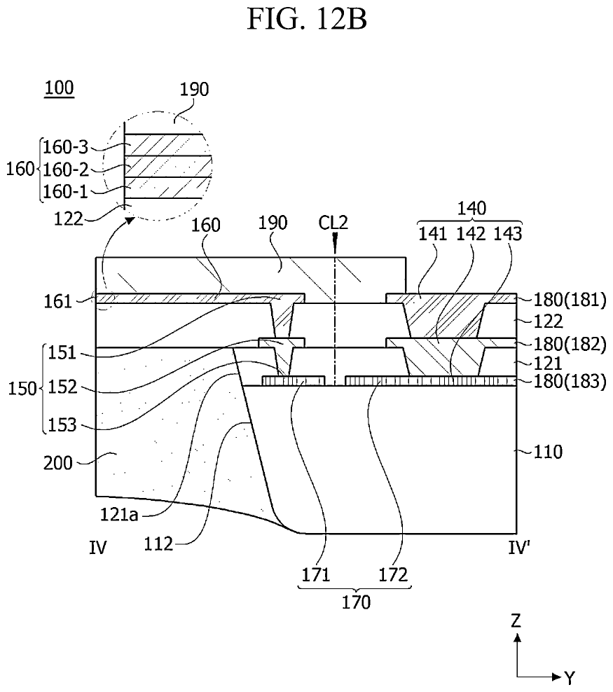

FIG. 12A is a cross-sectional view showing a display panel with respect to line IV-IV′ in FIG. 10 according to the first embodiment, and FIG. 12B is a diagram showing a coating layer of the display panel according to the first embodiment.

The display panel 100 according to the first embodiment can represent a display panel obtained after the first cutting process and second cutting process are performed on the semi-finished panel shown in FIG. 4A.

With reference to FIGS. 12A and 12B, the display panel 100 according to the first embodiment can include a substrate 110, an etch-stop layer 120 disposed on the substrate 110, a pad part 140, a bridge 150, a test line 160 connected to the bridge 150, a connection line 170 disposed between the pad part 140 and the bridge 150, a signal line 180 connected to one side of the pad part 140, and a protective layer 190 disposed on the second etch-stop layer 122 to expose a portion of the pad part 140. Here, the etch-stop layer 120 can include a first etch-stop layer 121 and a second etch-stop layer 122 disposed on the first etch-stop layer 121. Here, the test line 160 can be called a first line, the connection line 170 can be called a second line, and the signal line 180 can be called a third line. Additionally, the first line and the second line can be formed on the same layer, but without being limited thereto; in consideration of corrosion development, the first line and the second line can be formed on different layers. For example, the first line can be disposed on the second etch-stop layer 122 and the second line can be disposed on the substrate 110, thereby increasing the length of the path through which corrosion develops.

As shown in FIG. 12B, the display panel 100 according to the first embodiment can further include a coating layer 200 covering the side surface 112 of the substrate 110 and the side surface 121a of the first etch-stop layer 121 formed through an etching process. For example, a groove H1 can be formed concavely at the rear edge of the display panel 100 through an etching process and a cutting process, and the coating layer 200 can be disposed in the groove H1. Hence, the groove H1 can be disposed on the outside of the substrate 110 and the first etch-stop layer 121 through an etching process. Here, the inside can mean a direction toward the center of the display panel 100, and the outside can mean a direction opposite to the inside. Additionally, the surface of the display panel 100 on which the image is displayed can be referred to as the front surface, and the rear surface can refer to the surface opposite to the front surface.

The substrate 110 can be a glass substrate having a specified strength. Through the etching process, the side surface 112 of the substrate 110 can include a rounded edge. Additionally, the side surface 112 can be formed to have a gentle slope through the etching process. Consequently, the strength of the side surface 112 of the substrate 110 can be improved and the sharpness of the edge of the substrate 110 can be alleviated, thereby preventing cracks. At this time, with respect to the Y direction, the side surface 112 of the substrate 110 can be arranged to be more inwardly spaced than the exposed end portion 161 of the test line 160, and thus the display panel 100 can include the groove H1.

The etch-stop layer 120 can prevent the test line 160 and the like from being damaged by an etchant. At this time, the first etch-stop layer 121 can be thinner than the second etch-stop layer 122. Additionally, the first etch-stop layer 121 and the second etch-stop layer 122 can be made of different materials. For example, the first etch-stop layer 121 can include an inorganic insulating material, and the second etch-stop layer 122 can include an organic insulating material. In addition, the first etch-stop layer 121 can be the same layer as the interlayer insulating layer formed in the display area DA, and the second etch-stop layer 122 can be the same layer as the planarization layer formed in the display area DA. Further, the first etch-stop layer 121 and the second etch-stop layer 122 can each be composed of plural layers.

The first etch-stop layer 121 is disposed on the substrate 110, and a region thereof is etched through the etching process, thereby exposing a portion of the lower surface of the second etch-stop layer 122. For example, as the first etch-stop layer 121 is made of an inorganic insulating material, the groove H1 disposed on the outside of the substrate 110 can be extended to the lower surface of the second etch-stop layer 122 through the etching process. Here, the lower surface can mean one surface of the second etch-stop layer 122 being in contact with the first etch-stop layer 121.

The pad part 140 can be formed to penetrate through both of the first etch-stop layer 121 and the second etch-stop layer 122, and can be disposed on the substrate 110.

One side of the pad part 140 can be connected to the connection line 170 and the other side thereof can be connected to the signal line 180. Additionally, a flexible printed circuit board can be attached to the upper portion of the pad part 140.

The pad part 140 can include a first pad layer 141 disposed on the second etch-stop layer 122, a second pad layer 142 disposed on the first etch-stop layer 121, and a third pad layer 143 disposed on the substrate 110. At this time, the first pad layer 141, the second pad layer 142, and the third pad layer 143 can be electrically connected, and the first pad layer 141, the second pad layer 142, and the third pad layer 143 can overlap with each other in the Z direction. In addition, the first pad layer 141 and the second pad layer 142 can be electrically connected through a contact hole formed in the second etch-stop layer 122, and the third pad layer 143 can be electrically connected to the second pad layer 142 through a contact hole formed in the first etch-stop layer 121.

The first pad layer 141 and the second pad layer 142 can be made of the same material. For example, the first pad layer 141 and the second pad layer 142 can include titanium (Ti) and aluminum (Al), and can be formed in a three-layer structure like the first source and drain electrodes E11 and E12.

The first pad layer 141 can be electrically connected to a first signal line 181 of the signal lines 180, and a portion thereof can be exposed for coupling with a flexible printed circuit board.

The second pad layer 142 can be electrically connected to a second signal line 182 of the signal lines 180, and the third pad layer 143 can be electrically connected to a third signal line 183 of the signal lines 180.

The third pad layer 143 can be made of a material different from that of the first pad layer 141, and the third pad layer 143 can be formed together with the connection line 170 in the process of forming the connection line 170, but without being limited thereto. For example, in consideration of the resistance of the pad part 140, the third pad layer 143 can be made of the same material as the first pad layer 141. Consequently, the third pad layer 143 can be made of a material different from that of the connection line 170.

The bridge 150 can be disposed between the test line 160 and the pad part 140 for an electrical connection relationship. One side of the bridge 150 can be electrically connected to the test line 160, and the other side thereof can be electrically connected to the pad part 140 through the connection line 170.

The bridge 150 can be formed to penetrate the first etch-stop layer 121 and the second etch-stop layer 122, and can be disposed on the substrate 110. Hence, the bridge 150 can increase the length of the corrosion development path.

The bridge 150 can include a first bridge layer 151 disposed on the second etch-stop layer 122, a second bridge layer 152 disposed on the first etch-stop layer 121, and a third bridge layer 153 disposed on the substrate 110. At this time, the first bridge layer 151, the second bridge layer 152, and the third bridge layer 153 can be electrically connected, and the first bridge layer 151, the second bridge layer 152, and the third bridge layer 153 can overlap in the Z direction. In addition, the first bridge layer 151 and the second bridge layer 152 can be electrically connected through a contact hole formed in the second etch-stop layer 122, and the third bridge layer 153 can be electrically connected to the second bridge layer 152 through a contact hole formed in the first etch-stop layer 121.

The first bridge layer 151 and the second bridge layer 152 can be made of the same material. For example, the first bridge layer 151 and the second bridge layer 152 can include titanium (Ti) and aluminum (Al), and can be formed in a three-layer structure.

The third bridge layer 153 can be made of a material different from that of the first bridge layer 151 and the second bridge layer 152. For example, the third bridge layer 153 can include molybdenum (Mo) being resistant to corrosion. However, since the third bridge layer 153 can be formed together with the connection line 170 in the process of forming the connection line 170, it can be made of the same material as the connection line 170.

Since the test line 160 is a component for electrically connecting the AP pad 130 and the bridge 150, in the display panel 100 according to the first embodiment, the test line 160 can be arranged to be connected to the first bridge layer 151 of the bridge 150.

The test line 160 can be disposed on the second etch-stop layer 122 to prevent damage due to the etching process.

The test line 160 can be made of the same material as the first bridge layer 151. For example, the test line 160 can be made of a material containing titanium (Ti) and aluminum (Al), and can be formed in a three-layer structure like the first source and drain electrodes E11 and E12. For example, the test line 160 can include a first layer 160-1 made of Ti, a second layer 160-2 made of Al, and a third layer 160-3 made of Ti. At this time, as one end 161 of the test line 160 is exposed to the outside through the first cutting process, corrosion can occur in the test line 160. Also, depending on the material of the test line 160, the corrosion can develop along the inspection wiring 160.

The connection line 170 can electrically connect the bridge 150 and the pad part 140. For example, the connection line 170 can connect the first pad layer 141 and the first bridge layer 151, connect the second pad layer 142 and the second bridge layer 152, or connect the third pad layer 143 and the third bridge layer 153. At this time, the connection line 170 can be formed integrally with the third bridge layer 153, and can be made of molybdenum (Mo) being resistant to corrosion, preventing corrosion development.

The connection line 170 can control the length of the corrosion development path together with the bridge 150. For example, the connection line 170 can connect the third pad layer 143 and the third bridge layer 153 to maximize the length of the path through which corrosion develops along the test line 160. At this time, the connection line 170 can be formed through the same process as the third pad layer 143.

As the connection line 170 is cut through the second cutting process, corrosion development can be completely prevented in structure (e.g., the bridge 150 can contain corrosion development to remain spaced apart from the display area during earlier manufacturing steps, and then the bridge 150 can be isolated from the interior of the display panel by cutting a portion of the connection line 170 with a laser and the spread or threat of corrosion can be completely eliminated due to isolation of the bridge 150). At this time, the connection line 170 can include a first connection line 171 and a second connection line 172 separated by the second cutting process. Consequently, the first connection line 171 and the second connection line 172 can be arranged to be spaced apart from each other on the substrate 110. Here, the first connection line 171 can be connected to the third bridge layer 153, and the second connection line 172 can be connected to the third pad layer 143. Also, the first connection line 171 can be called a first part, and the second connection line 172 can be called a second part.

When the connection line 170 is formed of the first connection line 171 and the second connection line 172 arranged to be spaced apart from each other, the bridge 150 and the first connection line 171 can be made of the same material. For example, even if the entire bridge 150 is made of a material containing aluminum in consideration of resistance or the other, as the first connection line 171 and the second connection line 172 are separated, corrosion does not propagate to the second connection line 172. Accordingly, the first connection line 171 can also be made of a material containing aluminum like the bridge 150.

The signal lines 180 can be connected to the pad part 140 and can include a plurality of data lines and a plurality of gate lines. Additionally, the signal lines 180 can further include power lines such as a plurality of driving voltage lines and a plurality of reference voltage lines.

The signal lines 180 can include a first signal line 181 disposed on the second etch-stop layer 122, a second signal line 182 disposed on the first etch-stop layer 121, and a third signal line 183 disposed on the substrate 110.

The first signal line 181 can be made of the same material as the first pad layer 141, the second signal line 182 can be made of the same material as the second pad layer 142, and the third signal line 183 can be made of the same material as the third pad layer 143.

The protective layer 190 can be disposed on the second etch-stop layer 122 so that a portion of the pad part 140 is exposed, and can cover the test line 160.

The protective layer 190 can include a single-layer or multi-layer organic insulating material. For example, the second etch-stop layer 122 can include an organic material such as polyimide. Additionally, the protective layer 190 can be the same layer as the planarization layer formed in the display area DA, but without being limited thereto.

The coating layer 200 can be disposed under the second etch-stop layer 122 to overlap a portion of the test line 160. In this situation, the coating layer 200 can cover the side surface 112 of the substrate 110 and the side surface 121a of the first etch-stop layer 121 formed through the etching process. Here, the coating layer 200 can be made of an organic material containing a polyester-based polymer or an acrylic-based polymer.

Accordingly, the display panel 100 according to the first embodiment can reduce the sharpness of the edge of the substrate 110 which can help prevent crack formation while maintaining the rigidity of the substrate 110 by using an etching process.

In addition, the display panel 100 according to the first embodiment can prevent the test line 160 from being damaged due to an etching process by disposing the test line 160 on the second etch-stop layer 122.

In addition, the display panel 100 according to the first embodiment can use the position, structure, and/or material of the bridge 150 disposed to be spaced apart from the end portion 161 of the test line 160 to prevent corrosion development.

Further, the display panel 100 according to the first embodiment can prevent corrosion development by using the disconnection structure and/or material of the connection line 170.

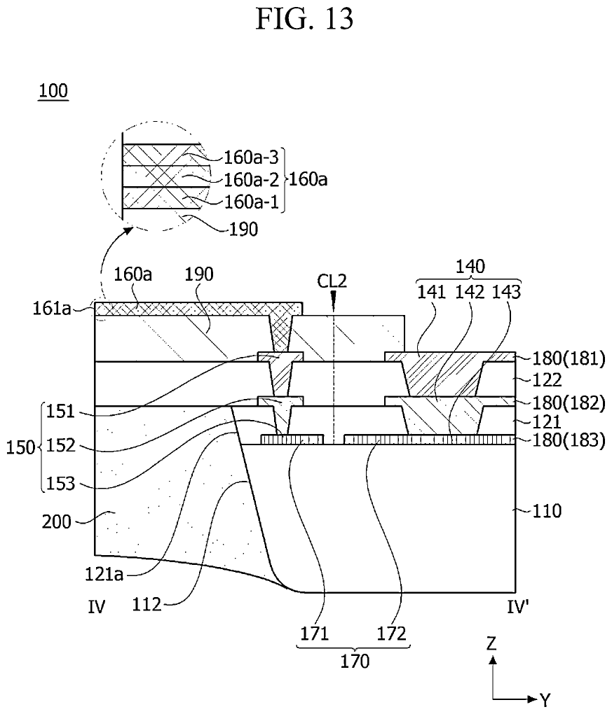

FIG. 13 is a cross-sectional view showing a display panel with respect to line IV-IV′ in FIG. 10 according to a second embodiment.

The display panel 100 according to the second embodiment can represent a display panel obtained after the first cutting process and second cutting process are performed on the semi-finished panel shown in FIG. 6. In describing the display panel 100 according to the second embodiment, the same components as those of the display panel 100 according to the first embodiment can be indicated by the same reference symbols, and thus detailed descriptions thereof will be omitted.

When comparing the display panel 100 according to the first embodiment and the display panel 100 according to the second embodiment with reference to FIGS. 12A, 12B and 13, there is a difference in that the test line 160a of the display panel 100 according to the second embodiment is disposed to be spaced farther apart from the first etch-stop layer 121 than the test line 160 of the display panel 100 according to the first embodiment.

With reference to FIG. 13, the display panel 100 according to the second embodiment can include a substrate 110, an etch-stop layer 120 disposed on the substrate 110, a pad part 140, a bridge 150, a test line 160a connected to the bridge 150, a connection line 170 disposed between the pad part 140 and the bridge 150, a signal line 180 connected to one side of the pad part 140, and a protective layer 190 disposed on a second etch-stop layer 122 to expose a portion of the pad part 140. Here, the etch-stop layer 120 can include a first etch-stop layer 121 and a second etch-stop layer 122 disposed on the first etch-stop layer 121. Additionally, the connection line 170 can include a first connection line 171 and a second connection line 172 separated by the second cutting process. Here, the test line 160a can be called a first wiring line, the connection line 170 can be called a second wiring line, and the signal line 180 can be called a third wiring line. In addition, the first wiring line and the second wiring line can be formed on the same layer, but without being limited thereto. In consideration of corrosion development, the first wiring line and the second wiring line can be formed on different layers. For example, the first wiring line can be disposed on the protective layer 190 and the second wiring line can be disposed on the substrate 110 to thereby increase the length of the path through which corrosion develops.

In addition, the display panel 100 according to the second embodiment can further include a coating layer 200 to cover the side surface 112 of the substrate 110 and the side surface 121a of the first etch-stop layer 121 formed through the etching process.

Since the test line 160a is a component for electrically connecting the AP pad 130 and the bridge 150, in the display panel 100 according to the second embodiment, the test line 160a can be connected to the first bridge layer 151 of the bridge 150. At this time, the test line 160a can be electrically connected to the first bridge layer 151 through a contact hole formed in the protective layer 190. Additionally, the test line 160 can be disposed on the protective layer 190 to prevent damage due to the etching process.

The test line 160a can be made of the same material as the first bridge layer 151. For example, the test line 160a can be made of a material containing titanium (Ti) and aluminum (Al), and can be formed in a three-layer structure. For example, the test line 160a can include a first layer 160a-1 made of Ti, a second layer 160a-2 made of Al, and a third layer 160a-3 made of Ti. In another embodiment, the test line 160a can be made of a material different from that of the first bridge layer 151. For example, the test line 160a can be made of a material containing indium tin oxide (ITO) and silver (Ag), and can be formed in a three-layer structure. For example, the test line 160a can include a first layer 160a-1 made of ITO, a second layer 160a-2 made of Ag, and a third layer 160a-3 made of ITO. At this time, the end portion 161a of the test line 160a can be exposed to the outside due to the first cutting process and corrosion can occur, and the corrosion can develop along the test line 160a depending on the material of the test line 160a.

The test line 160a can be formed together with the anode electrode AND formed in the display area DA in the process of forming the anode electrode AND, but without being limited thereto. That is, the test line 160a can be made of a material different from that of the anode electrode AND. For example, the test line 160a can be made of a material containing molybdenum (Mo) being resistant to corrosion.

Accordingly, the display panel 100 according to the second embodiment can reduce the sharpness of the edge of the substrate 110 to help prevent crack formation while maintaining the rigidity of the substrate 110 by using an etching process, and can further reduce the possibility of damage due to an etchant by disposing the test line 160a farther away on the protective layer 190 compared to the test line 160 of the display panel 100 according to the first embodiment.

In addition, the display panel 100 according to the second embodiment can use the position, structure, and/or material of the bridge 150 disposed to be spaced apart from the end portion 161a of the test line 160a to prevent corrosion development.

Further, the display panel 100 according to the second embodiment can prevent corrosion development by using the disconnection structure and/or material of the connection line 170.

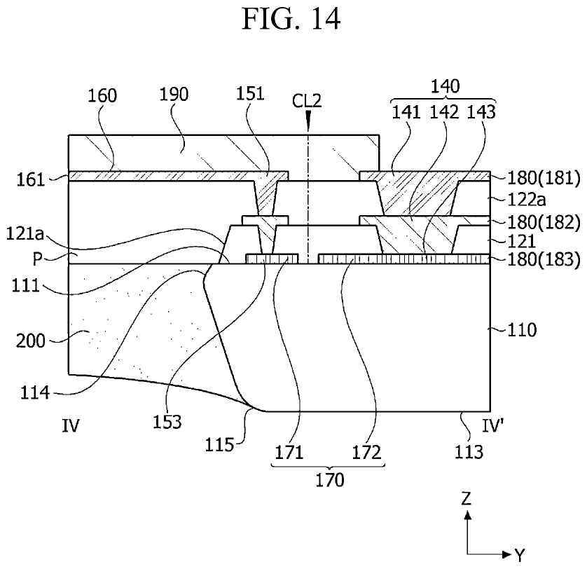

FIG. 14 is a cross-sectional view showing a display panel with respect to line IV-IV′ in FIG. 10 according to a third embodiment.

The display panel 100 according to the third embodiment can represent a display panel obtained after the first cutting process and second cutting process are performed on the semi-finished panel shown in FIG. 7. In describing the display panel 100 according to the third embodiment, the same components as those of the display panel 100 according to the first embodiment can be indicated by the same reference symbols, and thus detailed descriptions thereof will be omitted.

When comparing the display panel 100 according to the first embodiment and the display panel 100 according to the third embodiment with reference to FIGS. 12A, 12B and 14, there is a difference in that the second etch-stop layer 122a of the display panel 100 according to the third embodiment includes a protrusion P (e.g., the second etch-stop layer 122a can have a thick portion that contacts coating layer 200 in the groove H).

With reference to FIG. 14, the display panel 100 according to the third embodiment can include a substrate 110, an etch-stop layer 120a disposed on the substrate 110, a pad part 140, a bridge 150, a test line 160a connected to the bridge 150, a connection line 170 disposed between the pad part 140 and the bridge 150, a signal line 180 connected to one side of the pad part 140, and a protective layer 190 disposed on the etch-stop layer 120a to expose a portion of the pad part 140. Here, the etch-stop layer 120a can include a first etch-stop layer 121 and a second etch-stop layer 122a disposed on the first etch-stop layer 121. Additionally, the connection line 170 can include a first connection line 171 and a second connection line 172 separated by the second cutting process.

In addition, the display panel 100 according to the third embodiment can further include a coating layer 200 covering the side surface 112 of the substrate 110 formed through an etching process. For example, a groove H1 can be formed concavely at the edge of the display panel 100 through an etching process, and the coating layer 200 can be disposed in the groove H1. Hence, the groove H1 can be disposed on the outside of the substrate 110 through an etching process.

The second etch-stop layer 122a can include a protrusion P projecting toward the substrate 110.

The protrusion P can be disposed to cover the side surface 121a of the first etch-stop layer 121. Hence, the protrusion P can overlap with the first etch-stop layer 121 in the Y direction.

The protrusion P can be in contact with the upper surface 111 of the substrate 110.

The second etch-stop layer 122a has strong chemical resistance to an etchant, but its adhesive strength with the substrate 110 is relatively weaker compared to when the first etch-stop layer 121 is adhered to the substrate 110. Depending on the type of an organic material forming the second etch-stop layer 122a and the etching conditions, the edge where the upper surface 111 and the side surface 112 of the substrate 110 meet can be rounded to have a curved shape in the etching process. Additionally, the edge where the side surface 112 and the lower surface 113 of the substrate meet can be rounded to have a curved shape in the etching process. Consequently, the substrate 110 can include a first curved surface 114 formed at the edge where the upper surface 111 and the side surface 112 meet, and a second curved surface 115 formed at the edge where the side surface 112 and the lower surface 113 meet. Here, the etching conditions can include the etching time, flow rate of the etchant, fluid pressure of the etchant, and the other.

Since the first curved surface 114 can be formed by contact between the protrusion P and the etchant, the first curved surface 114 can overlap with the protrusion P in the Z direction. At this time, the protrusion P can overlap with the coating layer 200 in the Z direction.

The position and curvature of the second curved surface 115 can be adjusted depending on the position of a mask pattern disposed under the substrate 110. Considering that the side surface 112 is formed to be inclined by the etching solution, the second curved surface 115 can be spaced farther apart from the end portion 161 of the test line 160 than the first curved surface 114 with respect to the Y direction.

Accordingly, the display panel 100 according to the third embodiment can reduce the sharpness of the edge of the substrate 110 to help prevent crack formation while maintaining the rigidity of the substrate 110 by using an etching process. For example, the display panel 100 according to the third embodiment can alleviate the sharpness of the edge of the substrate 110 through at least two curved surfaces 114 and 115, which can help prevent the formation of cracks. For example, a sharp thin edge can be more fragile and more likely to crack.

In addition, the display panel 100 according to the third embodiment can prevent corrosion development by using the position, structure, and/or material of the bridge 150 disposed to be spaced apart from the end portion 161 of the test line 160.

Further, the display panel 100 according to the third embodiment can prevent corrosion development by using the disconnection structure and/or material of the connection line 170.

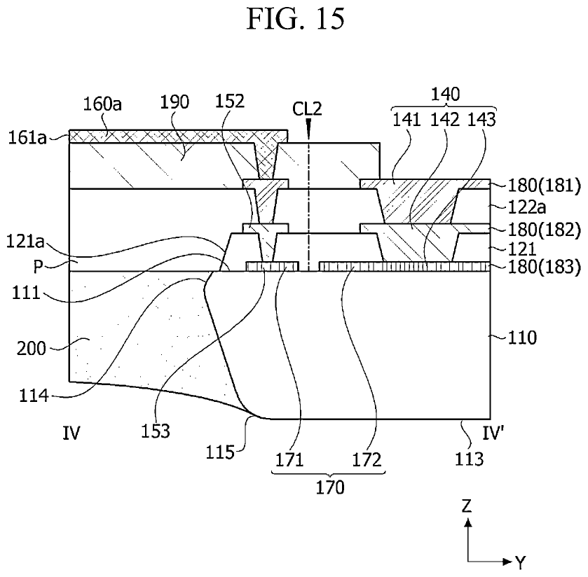

FIG. 15 is a cross-sectional view showing a display panel with respect to line IV-IV′ in FIG. 10 according to a fourth embodiment.

The display panel 100 according to the fourth embodiment can represent a display panel obtained after the first cutting process and second cutting process are performed on the semi-finished panel shown in FIG. 9. In describing the display panel 100 according to the fourth embodiment, the same components as those of the display panel 100 according to the first to third embodiments can be indicated by the same reference symbols, and thus detailed descriptions thereof will be omitted.

When comparing the display panel 100 according to the first embodiment and the display panel 100 according to the fourth embodiment with reference to FIGS. 12A, 12B and 15, there is a difference in that the test line 160a of the display panel 100 according to the fourth embodiment is arranged to be spaced farther apart from the first etch-stop layer 121 than the test line 160 of the display panel 100 according to the first embodiment, and the second etch-stop layer 122a includes a protrusion P.

With reference to FIG. 15, the display panel 100 according to the fourth embodiment can include a substrate 110, an etch-stop layer 120a disposed on the substrate 110, a pad part 140, a bridge 150, a test line 160a connected to the bridge 150, a connection line 170 disposed between the pad part 140 and the bridge 150, a signal line 180 connected to one side of the pad part 140, and a protective layer 190 disposed on the second etch-stop layer 122a to expose a portion of the pad part 140. Here, the etch-stop layer 120a can include the first etch-stop layer 121 and the second etch-stop layer 122a disposed on the first etch-stop layer 121. Additionally, the connection line 170 can include a first connection line 171 and a second connection line 172 separated by the second cutting process.

In addition, the display panel 100 according to the fourth embodiment can further include a coating layer 200 covering the side surface 112 of the substrate 110 formed through an etching process.

The second etch-stop layer 122a can include a protrusion P projecting toward the substrate 110. Here, the protrusion P can be formed integrally with the second etch-stop layer 122a.

The protrusion P can be disposed to cover the side surface 121a of the first etch-stop layer 121.

The protrusion P can be in contact with the upper surface 111 of the substrate 110.

Depending on the type of an organic material forming the second etch-stop layer 122a and the etching conditions, the substrate 110 can include a first curved surface 114 formed at the edge where the upper surface 111 and the side surface 112 meet, and a second curved surface 115 formed at the edge where the side surface 112 and the lower surface 113 meet.

Since the first curved surface 114 can be formed by contact between the protrusion P and the etchant, the first curved surface 114 and the coating layer 200 can be disposed to overlap the protrusion P in the Z direction.

The position and curvature of the second curved surface 115 can be adjusted depending on the position of a mask pattern disposed under the substrate 110, and the second curved surface 115 can be further spaced apart from the end portion 161 of the test line 160 than the first curved surface 114 with respect to the Y direction.

Accordingly, the display panel 100 according to the fourth embodiment can reduce the sharpness of the edge of the substrate 110 by using an etching process while maintaining the rigidity of the substrate 110, and can further reduce the possibility of damage due to an etchant by disposing the test line 160a on the protective layer 190 compared to the test line 160 of the display panel 100 according to the first embodiment.

In addition, the display panel 100 according to the fourth embodiment can prevent corrosion development by using the position, structure, and/or material of the bridge 150 disposed to be spaced apart from the end portion 161a of the test line 160a.

Further, the display panel 100 according to the fourth embodiment can prevent corrosion development by using the disconnection structure and/or material of the connection line 170.

The display device according to one or more embodiments of the present specification can be described as follows.

A display device according to one or more embodiments of the present specification can include a substrate disposed in a display area and a non-display area of a display panel; an etch-stop layer disposed on the substrate; a pad part and a bridge disposed to be spaced apart from each other on the substrate; a first wiring line connected to the bridge on one side and exposed on the other side; and a second wiring line disposed between the pad part and the bridge.

The display panel can include a concave groove formed at an edge of a rear surface thereof, and a side surface of the substrate can be disposed to be more inwardly spaced than an exposed end portion of the first wiring line due to the groove.

The side surface of the substrate can include a curved surface.

The etch-stop layer can include a first etch-stop layer disposed on the substrate and a second etch-stop layer disposed on the first etch-stop layer, and a material of the first etch-stop layer can be different from that of the second etch-stop layer.

The first etch-stop layer can include an inorganic insulating material, and the groove can be extended to a lower surface of the second etch-stop layer.

The second etch-stop layer further can include a protrusion, and the protrusion can be in contact with an upper surface of the substrate.

A lower surface, which can be an end surface of the protrusion, can be exposed by the groove.

The etch-stop layer can include a first etch-stop layer disposed on the substrate and a second etch-stop layer disposed on the first etch-stop layer; the pad part can include a first pad layer disposed on the second etch-stop layer and being exposed, a second pad layer disposed on the first etch-stop layer, and a third pad layer disposed on the substrate; and the first pad layer, the second pad layer, and the third pad layer are electrically connected.

The first pad layer and the second pad layer can be made of the same material.

The third pad layer can be made of a material different from that of the first pad layer.

The etch-stop layer can include a first etch-stop layer disposed on the substrate and a second etch-stop layer disposed on the first etch-stop layer, the bridge can include a first bridge layer disposed on the second etch-stop layer and being exposed, a second bridge layer disposed on the first etch-stop layer, and a third bridge layer disposed on the substrate; and the first bridge layer, the second bridge layer, and the third bridge layer can be electrically connected.

The first bridge layer and the second bridge layer can be made of the same material.

The third bridge layer can be made of a material different from that of the first bridge layer.

The etch-stop layer can include a first etch-stop layer disposed on the substrate and a second etch-stop layer disposed on the first etch-stop layer, and the first wiring line can be disposed on the second etch-stop layer.

The display device can further include a protective layer disposed on the second etch-stop layer to cover the first wiring line.

The first wiring line can include aluminum.

The display device can further include a protective layer disposed on the etch-stop layer, and the first wiring line can be disposed on the protective layer.

The second wiring line connects a third pad layer of the pad part disposed on the substrate and a third bridge layer of the bridge.

The second wiring line can be formed integrally with the third bridge layer.

The second wiring line can include molybdenum.

The second wiring line can include a first part and a second part disposed to be spaced apart from each other, the first part can be connected to the bridge, and the second part can be connected to the pad part.

A coating layer can be further disposed in the groove.

A display device according to one or more embodiments of the present specification can include a substrate disposed in a display area and a non-display area of a display panel; an etch-stop layer disposed on the substrate; a pad part and a bridge disposed to be spaced apart from each other on the substrate; a first wiring line connected to the bridge on one side and exposed on the other side; a first connection line connected to the bridge; and a second connection line connected to the pad part, in which the first connection line and the second connection line can be disposed to be spaced apart from each other.

The bridge and the first connection line are made of the same material.

The above description of the problem to be solved, the means to solve the problem, and the effect described above does not specify the essential features of the claims, and therefore the scope of the claims is not limited by what is described in the specification.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure, and the scope of the technical concept of the present disclosure is not limited thereto. Therefore, it should be understood that the embodiments described above are illustrative in all aspects and do not limit the present disclosure. The scope of protection of the present disclosure should be construed based on the following claims, and all technical concepts within the equivalent scope thereof should be construed as falling within the scope of the present disclosure.

What is claimed is:

1. A display device comprising:
a substrate disposed in a display area and a non-display area of a display panel;
an etch-stop layer disposed on the substrate;
a pad part and a bridge disposed on the substrate, the pad part and the bridge being spaced apart from each other;
a first wiring line having a first side connected to the bridge and a second side opposite to the first side, the second side being an end portion of the first wiring line; and
a second wiring line disposed between the pad part and the bridge.

2. The display device of claim 1, wherein the display panel includes a concave groove at an edge of a rear surface of the display panel, and
wherein a side surface of the substrate is spaced closer to the display area than the end portion of the first wiring line due to the concave groove.

3. The display device of claim 2, wherein the side surface of the substrate includes a curved surface.

4. The display device of claim 2, wherein the etch-stop layer includes a first etch-stop layer disposed on the substrate, and a second etch-stop layer disposed on the first etch-stop layer, and
wherein a material of the first etch-stop layer is different than a material of the second etch-stop layer.

5. The display device of claim 4, wherein the first etch-stop layer includes an inorganic insulating material, and
wherein the groove extends to a lower surface of the second etch-stop layer.

6. The display device of claim 4, wherein the second etch-stop layer further includes a protrusion that extends in a direction toward the groove, and
wherein a portion of the protrusion contacts an upper surface of the substrate.

7. The display device of claim 1, wherein the etch-stop layer includes a first etch-stop layer disposed on the substrate, and a second etch-stop layer disposed on the first etch-stop layer,
wherein the pad part includes a first pad layer disposed on the second etch-stop layer, a second pad layer disposed on the first etch-stop layer, and a third pad layer disposed on the substrate, and
wherein the first pad layer, the second pad layer, and the third pad layer are electrically connected to each other.

8. The display device of claim 7, wherein the first pad layer and the second pad layer both include a first type of material, and
wherein the third pad layer includes a second type of material that is different than the first type of material in the first pad layer and the second pad layer.

9. The display device of claim 1, wherein the etch-stop layer includes a first etch-stop layer disposed on the substrate, and a second etch-stop layer disposed on the first etch-stop layer,
wherein the bridge includes a first bridge layer disposed on the second etch-stop layer, a second bridge layer disposed on the first etch-stop layer, and a third bridge layer disposed on the substrate, and
wherein the first bridge layer, the second bridge layer, and the third bridge layer are electrically connected to each other.

10. The display device of claim 9, wherein the first bridge layer and the second bridge layer both include a first type of material, and
wherein the third bridge layer includes a second type of material that is different than the first type of material in the first bridge layer and the second bridge layer.

11. The display device of claim 1, wherein the etch-stop layer includes a first etch-stop layer disposed on the substrate, and a second etch-stop layer disposed on the first etch-stop layer, and
wherein the first wiring line is disposed on the second etch-stop layer.

12. The display device of claim 11, further comprising a protective layer disposed on the second etch-stop layer and overlapping with the first wiring line,
wherein the first wiring line includes aluminum.

13. The display device of claim 1, further comprising a protective layer disposed on the etch-stop layer,
wherein the first wiring line is disposed on the protective layer.

14. The display device of claim 1, wherein the second wiring line electrically connects a third pad layer of the pad part disposed on the substrate with a third bridge layer of the bridge.

15. The display device of claim 14, wherein the second wiring line is formed integrally with the third bridge layer.

16. The display device of claim 14, wherein the second wiring line includes molybdenum.

17. The display device of claim 1, wherein the second wiring line includes a first part and a second part spaced apart from each other,
wherein the first part of the second wiring line is connected to the bridge, and
wherein the second part of the second wiring line is connected to the pad part.

18. The display device of claim 2, further comprising a coating layer disposed in the groove.

19. A display device comprising:
a substrate disposed in a display area and a non-display area of a display panel;
an etch-stop layer disposed on the substrate;
a pad part and a bridge disposed on the substrate, the pad part and the bridge being spaced apart from each other;
a first wiring line having one side connected to the bridge and another side being an end portion of the first wiring line;
a first connection line connected to the bridge; and
a second connection line connected to the pad part,
wherein the first connection line and the second connection line are spaced apart from each other.

20. The display device of claim 19, wherein the bridge and the first connection line are made of a same material.

21. A display panel comprising:
a plurality of subpixels disposed in a display area of a substrate;
a pad part disposed in a non-display area of the substrate;
a bridge disposed in the non-display area of the substrate, the pad part being between the bridge and the display area;
a test line connected to a first side of the bridge, the test line extending away from the display area in a direction toward an outer edge of the display panel; and
a connection line connected to a second side of the bridge and the pad part.

22. The display panel of claim 21, further comprising:
an etch-stop layer disposed on the substrate;
a groove portion formed at an outer edge of the substrate, the test line and the etch-stop layer both overlapping with the groove portion; and
a coating layer disposed in the groove portion.

23. The display panel of claim 22, wherein the outer edge of the substrate includes an upper curved surface and a lower curved surface.

24. The display panel of claim 23, wherein the outer edge of the substrate includes an inclined side surface connected between the upper curved surface and the lower curved surface.

25. The display panel of claim 22, further comprising:
a protective layer disposed on the etch-stop layer,
wherein the protective layer is between the test line and the etch-stop layer.

26. The display panel of claim 22, wherein the etch-stop layer includes a first etch-stop layer disposed on the substrate, and a second etch-stop layer disposed on the first etch-stop layer,
wherein the second etch-stop layer includes a protrusion that extends in a direction toward the groove, and
wherein a portion of the protrusion contacts an upper surface of the substrate.

27. The display panel of claim 21, wherein the bridge includes a first bridge layer, a second bridge layer, and a third bridge layer, at least one layer among the first, second and third bridge layers including a different material than another layer among the first, second and third bridge layers, and
wherein the pad part includes a first pad layer, a second pad layer, and a third pad layer, at least one layer among the first, second and third pad layers including a different material than another layer among the first, second and third pad layers.

28. The display panel of claim 21, wherein the connection line is disconnected in an area between the bridge and the pad part.

29. The display panel of claim 21, wherein an end of the test line is part of the outer edge of the display panel.
